(19) United States
(12) Patent Application Publication
(10) Pub. No.: US 2016/0035990 A1
(43) Pub. Date: Feb. 4, 2016

(54) ACTIVE LAYER-INCORPORATED, SPECTRALLY-TUNED NANOSTRUCTURE-BASED LIGHT TRAPPING FOR ORGANIC PHOTOVOLTAIC DEVICES

(71) Applicant: THE REGENTS OF THE UNIVERSITY OF CALIFORNIA, Oakland, CA (US)

(72) Inventors: Vladan Jankovic, Santa Monica, CA (US); Yang Yang, Los Angeles, CA (US); Yang Yang, Los Angeles, CA (US); Jane Chang, Los Angeles, CA (US)

(21) Appl. No.: 14/775,079

(22) PCT Filed: Mar. 13, 2014
(86) PCT No.: PCT/US2014/026486

§ 371 Date: Sep. 11, 2015

Related U.S. Application Data
(60) Provisional application No. 61/780,232, filed on Mar. 13, 2013.

(51) Int. Cl. H01L 51/44; H01L 51/42

(52) U.S. Cl. CPC H01L 51/447; H01L 51/4266; H01L 51/448

(57) ABSTRACT

Core/shell resonant light absorption and scattering materials and methods incorporated into active layers for increasing the short circuit current and photo conversion efficiency of organic photovoltaic systems are provided. In particular, resonant light absorption and scattering methods and materials for improving the efficiency (short circuit current Qsc) and photo conversion efficiency (PCE)) of organic photovoltaic polymer systems (OPV) that include multilayer nano structures having a noble metal core and a passivated and functionalized outer shell disposed with the active layer of the OPV in the form of nanospheres and nanorods have been synthesized, characterized and incorporated into the active layers of OPV devices to enhance light absorption through plasmonic light trapping (PLT). In some embodiments the peak extinction wavelength of the nanoparticles is designed to coincide with the wavelength region of the OPV band edge in order to ensure that light trapping is occurring at wavelengths of poor absorption. In other embodiments, a second shell consisting of an optically active material is deposited onto the nanoparticles, the material being selected such that the extinction peak of the core of the nanoparticles is designed to coincide with the emission peak of the rare earth energy transition in order to increase the spontaneous emission rate at that wavelength by taking advantage of the Purcell effect.

### STATEMENT OF GOVERNMENT SUPPORT

This invention was made with Government support under Grant No. N00014-11-1-0250, awarded by the U.S. Navy, Office of Naval Research. The Government has certain rights in this invention.

### FIELD OF THE INVENTION

Plasmonic nanomaterials, and more specifically, spectrally-designed noble metal/oxide-based nanostructures, incorporated in the active layer of organic photovoltaics (OPVs) are described.

### BACKGROUND OF THE INVENTION

Given that its active layer is amenable to simple solution processing, organic photovoltaic (OPV) technology is an inexpensive, flexible and lightweight option for solar energy conversion. Research in organic solar cells started in the early 1980s and focused on Schottky junctions with low work-function metals and p-n junctions with p-type organic semiconducting polymers and inorganic n-type semiconductors. (See, e.g., Hiramoto, M., et al. Applied Physics Letters, 1991. 58(10): p. 1062-1064; Kirihata, H. and M. Uda, Review of Scientific Instruments, 1981. 52(1): p. 68-70; Loutfy, R. O. and J. H. Sharp, The Journal of Chemical Physics, 1979. 71(3): p. 1211-1217; Morel, D. L., et al., Applied Physics Letters, 1978. 32(8): p. 495-497; Wagner, H. J. and R. O. Loutfy, Journal of Vacuum Science and Technology, 1982. 20(3): p. 300-304; Yokoyama, M., et al., The Journal of Chemical Physics, 1981. 75(6): p. 3006-3011; and Yokoyama, M., et al., The Journal of Chemical Physics, 1982. 76(1): p. 724-728, the disclosures of which are incorporated herein by reference.) Interest in the field intensified after Tang et al. demonstrated an OPV device in 1986 with a 0.95% efficiency using organic polymers as both donors and acceptors. (See, e.g., Tang, C. W., Applied Physics Letters, 1986. 48(2): p. 183-185, the disclosure of which is incorporated herein by reference.)

Other breakthroughs in OPV technology came with the introduction of buckminsterfullerene (C₆₀) and its derivatives such as [6,6]-phenyl-C₆₀-butyric acid methyl ester (PC₆₀BM) as n-type organic materials by Sariciftci et. al., and with the development of the bulk heterojunction (BHJ) by Hiramoto et al. (See, Sariciftci, N. S., et al., Applied Physics Letters, 1993. 62(6): p. 585-587; Sariciftci, N. S., et al., Science, 1992. 258(5087): p. 1474-1476; and Hiramoto, et al. Journal of Applied Physics, 1992. 72(8): p. 3781-3787, the disclosures of which are incorporated herein by reference.)

Seminal BHJ OPV papers using poly(2-methoxy-5(20-ethylhexyloxy)-1,4-phenylenevinylene (MEH-PPV) as the donor molecule and PC₆₀BM as the acceptor molecule were published by the Heeger and Friend groups independently in 1995. (See, e.g., Yu, G., et al., Science, 1995. 270(5243): p. 1789-1791; and Marks, R. N., et al., Journal of Physics: Condensed Matter, 1994. 6(7): p. 1379, the disclosures of which are incorporated herein by reference.) As research in the field continued, studies revealed that the nanoscale morphology of the active layer of OPV devices was critical for optimizing their efficiency. (See, e.g., Goetzberger, A., et al. Materials Science and Engineering: R: Reports, 2003. 40(1): p. 1-46; and Li, W. W., et al., Organic Electronics, 2011. 12(9): p. 1544-1551, the disclosures of which are incorporated herein by reference.)

Numerous strategies, including solvent selection, thermal annealing, and the incorporation of various additives have led to improved active layer morphologies and consequently further improvements in photon conversion efficiencies (PCEs). (See, e.g., Duong, D. T., et al., Journal of Polymer Science Part B-Polymer Physics, 2012. 50(20): p. 1405-1413; Fang, G., et al., Organic Electronics, 2012. 13(11): p. 2733-2740; Song, Y. and 5.0. Ryu, Journal of Nanoelectronics and Optoelectronics, 2012. 7(5): p. 549-553; Ma, W., et al., Advanced Functional Materials, 2005. 15(10): p. 1617-1622; and Brady, M. A., et al. Soft Matter, 2011. 7(23): p. 11065-11077, the disclosures of which are incorporated herein by reference.) High carrier mobility, donor conjugated polymers such as poly(3-hexylthiphene) (P3HT) and low-bandgap polymers such as poly[2,6-4,8-di(5-ethylhexylthienyl)benzo[1,2-b;3,4-b]dithiophene-alt-5-dibutyloctyl-3,6-bis(5-bromothiophen-2-yl) pyrrolo[3,4-c]pyrrole-1,4-dione] (PBDTT-DPP) whose absorption extends up to A-850 nm have also led to PCE improvements. (See, e.g., Padinger, F., et al. Advanced Functional Materials, 2003. 13(1): p. 85-88; and Li, G., et al. Nat Photon, 2012. 6(3): p. 153-161, the disclosures of which are incorporated herein by reference.) Currently, a PCE of over 9% for single-junction OPVs has been achieved by Mitsubishi Chemical and a NREL-certified PCE of 10.6% has been achieved for tandem cells by Li et. al. (See, e.g., Service, R. F., Science, 2011. 332(6027): p. 293, the disclosure of which is incorporated herein by reference.)

Accordingly, a need exists to develop more efficient OPVs to improve performance and accelerate adoption.

### SUMMARY OF THE INVENTION

Embodiments of the invention are directed to plasmonic/fluorescent nanomaterials, such as, spectrally-designed noble metal/oxide-based nanostructures that operate as resonant light absorption and scattering materials for increasing the photo conversion efficiency of organic photovoltaic systems, such materials including:
a multilayer nanostructure having a core formed of a noble metal and having a shell disposed thereon having:
   a first shell layer disposed atop the core being formed of a passivating material, and
   a second shell layer disposed atop the first shell layer being formed of an optically active material said first shell layer being or optically active character;
wherein the multilayer nanostructure has disposed thereon at least one functional ligand capable of placing the nanostructure into solution with an organic solvent in an active layer of an organic photovoltaic system;
wherein the core of the nanostructure exerts a local surface plasmon resonance near field absorption enhancement over the absorption of light by the organic photovoltaic active layer over the wavelength band of the plasmon resonance of the nanostructure core; and
wherein the optically active material has optical activity at a wavelength band that overlaps with the peak extinction of the local surface plasmon resonance wavelength band of the nanostructure core.

In some embodiments the nanostructure is a non-symmetric elongated body, selected from one of a nanosphere, nanostar, nanocube and nanorod.

In other embodiments the noble metal is selected from the group consisting of palladium, silver, platinum and gold, wherein the passivation layer is an oxide, and wherein the optically active material is a rare earth material.

Some embodiments of the invention are directed to organic photovoltaic systems including:
an active light absorbing layer, said layer being formed of an organic polymer;
a plurality of multilayer nanostructures each having:
   a core formed of a noble metal,
   a shell disposed thereon formed of a passivating material, and
   wherein the multilayer nanostructure has disposed thereon at least one functional ligand capable of placing the nanostructure into solution with the organic polymer in the active layer; and
wherein the core of the nanostructure exerts a local surface plasmon resonance near field absorption enhancement over the absorption of light by the organic photovoltaic active layer over the wavelength band of the plasmon resonance of the nanostructure core.

In some embodiments the nanostructure is a non-symmetric elongated body, selected from one of a nanosphere, nanostar, nanocube and nanorod.

In other embodiments the noble metal is selected from the group consisting of palladium, silver, platinum and gold.

In still other embodiments the absorption and scattering of the nanostructure is at least partially controlled by the size and geometry of the noble metal core.

In yet other embodiments the shell is a passivation layer that is electrically insulating.

In still yet other embodiments the passivating material is an oxide.

In still yet other embodiments the functional ligand is an organosilane.

In still yet other embodiments the nanostructures are disposed within the active light absorbing layer in a concentration of from 0.4 to 2.0 mg/ml.

Other embodiments of the invention are also directed to organic photovoltaic system including:
an active light absorbing layer, said layer being formed of an organic polymer;
a plurality of multilayer nanostructures each having:
   a core formed of a noble metal,
   a first shell layer disposed atop the core being formed of a passivating material,
   a second shell layer disposed atop the first shell layer being formed of an optically active material, and
wherein the multilayer nanostructure has disposed thereon at least one functional ligand capable of placing the nanostructure into solution with the organic polymer in the active layer;
wherein the core of the nanostructure exerts a local surface plasmon resonance near field absorption enhancement over the absorption of light by the organic photovoltaic active layer over the wavelength band of the plasmon resonance of the nanostructure core; and
wherein the optically active material has optical activity at a wavelength band that overlaps with the peak extinction of the local surface plasmon resonance wavelength band of the nanostructure core.

In some embodiments the nanostructure is a non-symmetric elongated body, selected from one of a nanosphere, nanostar, nanocube and nanorod.

In other embodiments the noble metal is selected from the group consisting of palladium, silver, platinum and gold.

In still other embodiments the absorption and scattering of the nanostructure is at least partially controlled by the size and geometry of the noble metal core.

In yet other embodiments the shell is a passivation layer that is electrically insulating.

In still yet other embodiments the passivating material is an oxide.

In still yet other embodiments the functional ligand is an organosilane.

In still yet other embodiments the optically active layer is formed of Er³⁺:Y₂O₃.

In still yet other embodiments the nanostructures are disposed within the active light absorbing layer in a concentration of from 0.4 to 2.0 mg/ml.

Additional embodiments and features are set forth in part in the description that follows, and in part will become apparent to those skilled in the art upon examination of the specification or may be learned by the practice of the disclosed subject matter. A further understanding of the nature and advantages of the present disclosure may be realized by reference to the remaining portions of the specification and the drawings, which forms a part of this disclosure.

### BRIEF DESCRIPTION OF THE DRAWINGS

The description will be more fully understood with reference to the following figures and data graphs, which are presented as exemplary embodiments of the invention and should not be construed as a complete recitation of the scope of the invention, wherein:

FIG. 1A illustrates a schematic of a resonant light absorption nanomaterial in accordance with embodiments.

FIG. 1B illustrates a schematic of an optically active resonant light absorption nanomaterial in accordance with embodiments.

FIG. 2 illustrates a schematic of an OPV device in accordance with embodiments.

FIG. 3A provides a data plot showing resonance wavelengths for a number of nanostructures in accordance with embodiments.

FIGS. 3B to 3D provide data of simulated absorption and scattering cross sections of Au/SiO₂ ellipsoids of: B) different aspect ratios transverse ellipsoid diameter is each spectrum is 10 nm); and C) absorption and D) scattering cross sections of Au/SiO₂ ellipsoids of aspect ratio 2.5 but with different shapes (transverse ellipsoid diameter is shown next to absorption cross section).

FIGS. 4A and 4B provide: A) from left to right, TEM images of Au & Au/SiO₂ core/shell nanospheres, Au & Au/SiO₂ core/shell nanorods of AR˜2.5, Au & Au/SiO₂ core/shell nanorods of AR˜4; and B) extinction spectra of corresponding colloidal solutions in accordance with embodiments.

FIGS. 5A to 5D provide: the chemical structure of A) P3HT:PC₆₀BM; B) normalized EQE of P3HT:PC₆₀BM, normalized extinction of Au/SiO₂ core/shell nanospheres and AR˜2.5 Au/SiO₂ core/shell nanorods shown in FIG. 4A; C) PBDTT-DPP:PC₆₀BM; and D) normalized EQE of PBDTT-DPP:PC₆₀BM, normalized extinction of Au/SiO₂ core/shell nanospheres and AR˜2.5 Au/SiO₂ core/shell nanorods shown in FIG. 4A in accordance with embodiments.

FIGS. 6A to 6D provide data from solar cell PCEs as a function of: Au/SiO₂ core/shell nanospheres in A) P3HT:PC₆₀BM and B) PBDTT-DPP:PC₆₀BM; and nanorod concentrations in A) P3HT:PC₆₀BM and B) PBDTT-DPP:PC₆₀BM incorporated in the active layers of OPVs in accordance with embodiments.

FIGS. 7A to 7F provide atomic force microscopy images of P3HT:PCB₆₀M devices (the left column is the height image and the right column the phase image): (a-b) reference device, (c-d) device with 0.6 mg/ml Au/SiO₂ nanospheres, and (e-f) device with 3 mg/ml Au/SiO₂ nanospheres.

FIGS. 8A to 8F provide atomic force microscopy images of PBDTT-DPP:PCB₆₀M devices (the left column is the height image and the right column the phase image): (a-b) reference device, (c-d) device with 0.6 mg/ml Au/SiO₂ nanospheres, and (e-f) device with 1 mg/ml Au/SiO₂ nanospheres.

FIGS. 9A and 9B provide plots of: EQE enhancements of A) P3HT:PC₆₀BM and B) PBDTT-DPP:PC₆₀BM polymers with Au/SiO₂ core/shell nanospheres and nanorods (shown in FIG. 4A incorporated in OPV active layers in accordance with embodiments.

FIGS. 10A to 10D provide data plots where: A) normalized EQE of a P3HT:PC₆₀BM OPV device and normalized extinction of Au/SiO₂ core/shell nanospheres; B) EQE of a reference P3HT:PC₆₀BM OPV device and one with Au/SiO₂ core/shell nanospheres (λₚₑₐₖ=540 nm); C) Normalized EQE of P3HT:PC₆₀BM OPV device and normalized extinction of Au/SiO₂ core/shell nanorods (λₚₑₐₖ=680 nm); and D) EQE of a reference P3HT:PC₆₀BM OPV device and one with Au/SiO₂ core/shell nanorods (λₚₑₐₖ=680 nm) in accordance with embodiments.

FIGS. 11A to 11D provide data plots where: A) normalized EQE of PBDTT-DPP:PC₆₀BM and normalized extinction of Au/SiO₂ core/shell nanospheres; B) EQE of a reference PBDTT-DPP:PC₆₀BM OPV device and one with Au/SiO₂ core/shell nanospheres (Δₚₑₐₖ=540 nm); C) Normalized EQE of PBDTT-DPP:PC₆₀BM and normalized extinction of Au/SiO₂ core/shell nanorods (λₚₑₐₖ=830 nm); and D) EQE of a reference PBDTT-DPP:PC₆₀BM OPV device and one with Au/SiO₂ core/shell nanorods (Δₚₑₐₖ=830 nm) in accordance with embodiments.

FIG. 12 provides data plots of normalized extinction spectra of Au/SiO₂/Yb:Er:Y₂O₃, SiO₂/Yb:Er:Y₂O₃ and Au/SiO₂ solutions along with emission spectrum associated with the Er^{3+ 4}F9/2→⁴I_{15/2} radiative energy transition.

FIGS. 13A to 13C provide data plots of the upconversion power spectra (980 nm laser diode excitation) of A) Au/SiO₂, and B) SiO₂/Yb:Er:Y₂O₃; and C) Au/SiO₂/Yb:Er:Y₂O₃.

FIGS. 14A and 14B provide data plots of: A) power dependence spectra of samples Au/SiO₂/Yb:Er:Y₂O₃, SiO₂/Yb:Er:Y₂O₃ and Au/SiO₂; and B) the radiative lifetime measurements for Au/SiO₂/Yb:Er:Y₂O₃ and SiO₂/Yb:Er:Y₂O₃.

FIG. 15A shows simulated absorption cross sections of Au/SiO₂ core/shell nanorods of 12 nm diameter, 30 nm length, 10 nm thick SiO₂ shell (12×30, 10 nm), Au/SiO₂ core/shell nanorods of 10 nm diameter, 40 nm length with a 5 nm thick SiO₂ shell (10×25, 5 nm) and experimental emission cross section spectra of the 4F9/2→4I15/2 energy transition of Er³⁺ (˜655 nm) and the 3H4→3H6 energy transition of Tm³⁺ (˜805 nm).

FIG. 15B shows experimental extinction spectra of Au/SiO₂/Yb:Er:Y₂O₃ and Au/SiO₂/Yb:Tm:Y₂O₃ core/shell nanorods of aspect ratio 2.5 and 4 respectively along with experimental emission spectra associated with the Er³⁺ 4F9/2→4I15/2 and the Tm³⁺ 3H4→3H6 energy transition.

### DETAILED DESCRIPTION OF THE INVENTION

Turning now to the drawings, plasmonic/fluorescent nanomaterials, and more specifically resonant light absorption and scattering materials and methods for increasing the short circuit current and photo conversion efficiency of organic photovoltaic (OPV) systems are described. In some embodiments, the OPV-solvent compatible plasmonic/dielectric core/shell nanoparticles are incorporated in the active layer of the OPVs. In many embodiments the nanomaterials incorporate noble metal nanostructures, such as, for example, Au as sub-wavelength scattering centers. In other embodiments the nanomaterials incorporate a passivating shell, such as, for example, a SiO₂ material. In many other embodiments the nanomaterials incorporate optically active rare earth shells, such as, for example, a Yb:Er:Y₂O₃ material.

### Theories Of OPV Device Efficiency

Photons absorbed by an OPV device can only generate current if they are absorbed near donor-acceptor interfaces such that dissociation occurs prior to dissipative recombination, however, since the carrier mobility is small in photo-active polymers (on the order of 10⁻⁴ cm²/Vs, or less), it is common to use rather thin films (100 nm or less) in order to achieve efficient carrier extraction. (See, e.g., Park, S. H., et al., Bulk heterojunction solar cells with internal quantum efficiency approaching 100%. 2009. 3(5): p. 297-302, the disclosure of which is incorporated herein by reference.) The use of such thin layers means a significant portion of the incident photon flux remains unharvested; it also means that obtaining high light absorption efficiencies in OPV devices is crucial to making practical devices.

One method of improving light absorption efficiency of OPVs is to incorporate light trapping layers or materials into the OPV device. From a ray-optics perspective, conventional light trapping employs total internal reflection by patterning the entrance or exit interfaces of the solar cell and redirecting the incident light into the PV active layer. (See, Deckman, H. W., et al. Opt. Lett. Optics Letters, 1983. 8(9): p. 491-493, the disclosure of which is incorporated herein by reference.) In thick crystalline silicon (Si) solar cells, light trapping is typically achieved with the use of patterned structures that have features on the scale of the wavelength of light. (See, Battaglia, C., et al., ACS Nano, 2012. 6(3): p. 2790-2797, the disclosure of which is incorporated herein by reference.) Since the active layers in organic cells have thicknesses that are far smaller than the wavelength of light, the relatively large-scale geometries used in traditional light trapping designs are not suitable for OPVs. (See, Atwater, H. A. and A. Polman, Plasmonics for improved photovoltaic devices. 2010. 9(3): p. 205-213, the disclosure of which is incorporated herein by reference.) For OPV applications, it is imperative to develop light trapping techniques that rely on structures compatible with the scale of OPV films, in other words, at a scale less than 100 nm. (See, Qiaoqiang, G., et al. Photonics Journal, IEEE, 2012. 4(2): p. 620-624, the disclosure of which is incorporated herein by reference.)

One light trapping method that is promising for OPV applications involves the use of noble metals (mainly gold (Au) or silver (Au) nanoparticles). (See, e.g., Atwater, H. A. and A. Polman, Plasmonics for improved photovoltaic devices. 2010. 9(3): p. 205-213, the disclosure of which is incorporated herein by reference.) Noble metal nanoparticles have a unique interaction with light due to a resonant collective oscillation of the noble metal nanoparticle free electrons, termed the localized surface plasmon resonance (LSPR). The movement of the conduction electrons upon excitation with incident light acts as a restoring force and leads to a buildup of polarization charges on the nanoparticle surface. Due to this phenomenon, noble metal nanoparticles exhibit strongly enhanced absorption and scattering cross sections at the LSPR frequency, greatly exceeding the geometrical cross section of the nanoparticles. For example, an Ag nanoparticle in air has a scattering cross section that is around ten times the geometrical cross-sectional area of the particle; hence, a substrate covered with a 10% areal density of Ag particles could ideally absorb and scatter all the light incident on the substrate. (See, e.g., Catchpole, K. R. and A. Polman, Opt. Express, 2008. 16(26): p. 21793-21800, the disclosure of which is incorporated herein by reference.)

Noble metal nanoparticles deposited on the top of thin film solar cells have been shown to preferentially scatter light into the high-index substrate, leading to enhanced coupling with the underlying semiconductor and thus a reduced reflectance over a broad spectral range. (See, e.g., Spinelli, P., et al., Journal of Optics, 2012. 14(2): p. 024002, the disclosure of which is incorporated herein by reference.) Noble metal nanoparticles can also be used as subwavelength antennas incorporated into the active layer of the OPV device. (See, e.g., Atwater, H. A., 2010, cited above.) When embedded in the active layer, the LSPR near-field of the nanoparticle can increase exciton generation rates in the semiconductor due to the locally enhanced electromagnetic field. This is particularly useful in materials where the carrier diffusion lengths are short, like in OPV materials. (See, e.g., Rand, B. P., et al. Journal of Applied Physics, 2004. 96(12): p. 7519-7526, the disclosure of which is incorporated herein by reference.)

Light trapping with Au and Ag nanoparticles for OPVs has been demonstrated by various groups. By incorporating Au nanospheres (˜45 nm diameter) into the poly(ethylenedioxythiophene):polystyrenesulphonate (PEDOT:PSS) buffer layer of a P3HT:PC₆₀BM OPV device, Morfa et. al. increased the PCE of the device from 1.3% to 2.2%. (See, e.g., Morfa, A. J., et al., Applied Physics Letters, 2008. 92(1): p. 013504-3, the disclosure of which is incorporated herein by reference. Qiao et. al. showed that Au nanoparticles (˜15 nm diameter) introduced into the PEDOT:PSS buffer layer of an OPV device using poly(2-methoxy-5(20-ethylhexyloxy)-1,4-phenylenevinylene (MEH-PPV) as the active layer enhanced the PCE from 1.99% to 2.36%. (See, e.g., Qiao, L., et al., Applied Energy, 2011. 88(3): p. 848-852, the disclosure of which is incorporated herein by reference.) Wu et. al. demonstrated that incorporating Au nanoparticles (˜45 nm diameter) into the anodic buffer layer of a P3HT:PC₆₀BM OPV device improved the PCE from 3.57% to 4.24%. (See, e.g., Wu, J.-L., et al., ACS Nano, 2011. 5(2): p. 959-967, the disclosure of which is incorporated herein by reference.) More recently, Au nanoparticles (˜72 nm diameter) were deposited in the interconnecting layer of an inverted tandem polymer solar cell, resulting in a 20% increase in PCE (from 5.22% to 6.24%). (See, e.g., Yang, J., et al., Acs Nano, 2011. 5(8): p. 6210-6217, the disclosure of which is incorporated herein by reference.)

In all of these reports, because the plasmonic nanoparticles were inserted relatively far from the active organic layers of the OPV devices, and more particularly in the buffer layer, the documented absorption enhancements arose solely from the light scattering properties of the Au nanoparticles and failed to exploit the near-field enhanced LSPR modes. (See, e.g., Qiaoqiang, G., F. J. Bartoli, and Z. H. Kafafi, Photonics Journal, IEEE, 2012. 4(2): p. 620-624, the disclosure of which is incorporated herein by reference.) However, theoretical studies have shown, embedding plasmonic nanoparticles into the active layer of an OPV device can capitalize on both the light scattering effect and the enhanced LSPR near field. (See, e.g., Lee, J.-Y. and P. Peumans, Opt. Express, 2010. 18(10): p. 10078-10087; and Qu, D., et al., Opt. Express, 2011. 19(24): p. 24795-24803, the disclosures of which are incorporated herein by reference.)

Currently, there are only a few reports documenting incorporation of plasmonic materials into OPV active layers. Szeremeta et. al. showed that Cu nanoparticles (20 nm) embedded inside P3HT layers enhanced the dissociation of excitons without increasing the P3HT optical absorption. (See, e.g., Szeremeta, J., et al., Optical Materials, 2011. 33(9): p. 1372-1376, the disclosure of which is incorporated herein by reference.) Wang et. al. demonstrated improved PCEs in three different polymer systems resulting from incorporation of Au nanoparticles in the active layer but the observed EQE enhancements were broadband, indicating that the enhancements were due to light scattering and not due to the narrow band LSPR near field. (See, e.g., Wang, D. H., et al., Angewandte Chemie International Edition, 2011. 50(24): p. 5519-5523, the disclosure of which is incorporated herein by reference.) Mei et. al. incorporated Ag nanoparticles into the active layer of a P3HT:PC₆₀BM OPV device and found that while their addition into the active layer significantly enhanced carrier mobility, it decreased the total extracted carrier density. (See, e.g., Xue, M., et al., Applied Physics Letters, 2011. 98(25): p. 253302 (3 pp.)-253302 (3 pp.), the disclosure of which is incorporated herein by reference.) A potential way to address some of these issues is to coat the noble metal nanoparticles with a thin layer of SiO₂ rendering their surfaces insulating yet still retain their attractive optical properties.

### OPV Enhancing Nanomaterials

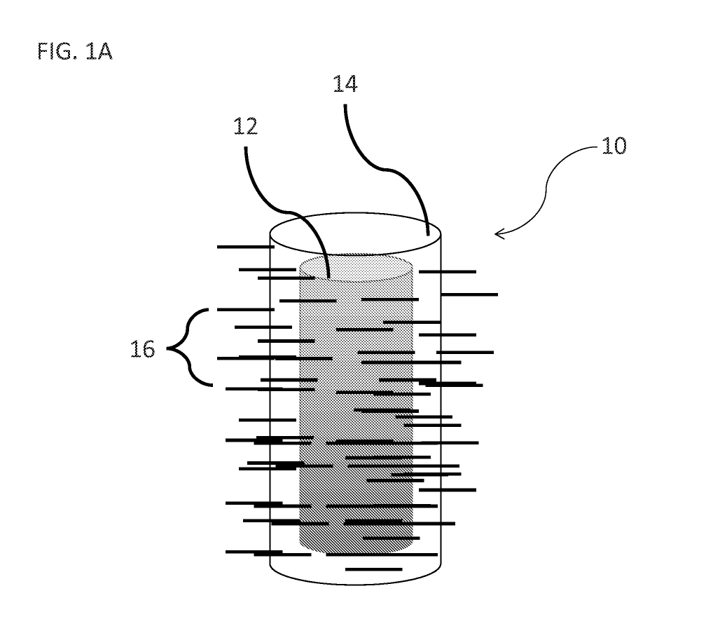

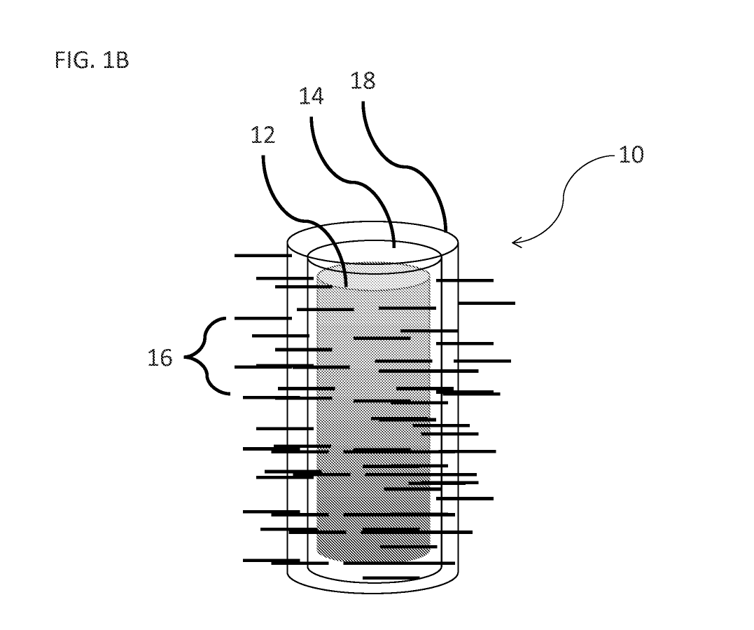

Embodiments of plasmonic/fluorescent nanomaterials configured to operate as resonant light absorption and scattering materials for improving the efficiency (short circuit current (J_{SC}) and photo conversion efficiency (PCE)) of organic photovoltaic polymer systems (OPV), and methods of their use are described. As shown in FIG. 1A, in many embodiments the nanomaterials include multilayer nanostructures (10) having a noble metal core (12) and a passivated (14) and functionalized (16) outer shell disposed within the active layer of the OPV and capable of exerting a resonance enhancement on the light absorption of the active layer. Although a core/shell nanomaterial having a single outer shell structure is shown and described above, it should be understood that multiple shell layers (14 & 18) may be utilized, as shown in FIG. 1B. In such embodiments, the shell layers may serve different functions, a first shell layer (14) may include a passivation material and a second shell layer (18) may include an optically active layer.

In some embodiments, the nanostructure is a rod, tube, sphere, cage, star or cube, and the noble metal is selected from the group consisting of palladium, silver, platinum and gold. In many embodiments, the relative light absorption or scattering contribution to the overall nanoparticle optical response can be designed by changing the size and geometry of noble metal core (larger nanoparticles generally scatter light more efficiently than smaller particles which tend to absorb the majority of the incident light upon them). For example, OPV devices with plasmonic materials embedded in their active layers have to make a tradeoff between incorporating small (<30 nm) nanoparticles (which preferentially absorb light, but disturb active layer morphology to a lesser degree that larger particles) and larger (>50 nm) nanoparticles (which preferentially scatter light but potentially disturb active layer morphology to a greater degree). Likewise, the shape of the nanoparticles assists in the ability to spectrally tune the peak extinction wavelength of the nanoparticles for optimizing their efficacy for specific applications. For these purposes, nonsymmetric nanoparticles, such as nanorods, have several advantages over the more commonly employed Au nanospheres. Unlike Au nanospheres, Au nanorods have two distinct LSPR bands: a transverse and a longitudinal band. The former (located from ˜520 nm to ˜540 nm, depending on the nanorod radius) corresponds to light absorption and scattering along the short axis of the Au nanorod. The longitudinal LSPR bands correspond to light absorption and scattering along the long axis; this band is much stronger and tunable from the visible to near infrared (NIR) region with increasing aspect ratio of the nanorod. Accordingly, in many embodiments the nanoparticles take the form of a nonsymmetric particle, such as a nanorod, which results in a stronger LSPR band to make the nanoparticles more sensitive to changes in their size, shape, and nano-environment as well as interparticle distance, improve LSPR tunability thus improving the efficiency of fluorescence quenching and enhancement through resonant energy transfer and improving LSPR tunability of two-photon luminescence (TPL).

In many embodiments, a passivating shell layer (such as an oxide material like SiO₂) is added onto the Au core nanospheres and nanorods in order to provide an electrically insulating surface that doesn't interfere with carrier generation and transport inside the active layer, such as by serving as exciton recombination sites which degrade OPV device performance. It should be understood that although any suitable electrically insulating or passivating coating material may be used, such as SiO₂, the thickness of the passivating layer must be sufficiently thin such that it does not interfere with the LSPR near field of the resonance nanostructure. Increasing the SiO₂ shell thickness will concentrate the majority of the near field enhancement from the LSPR in the SiO₂ shell. (See, e.g., Rodríguez-Fernández, J., et al., The Journal of Physical Chemistry C, 2007; 111(36): p. 13361-13366, the disclosure of which is incorporated herein by reference.) Hence, observed EQE enhancements derived from incorporation of Au/SiO₂ core/shell nanoparticles with thicker SiO₂ shells (>30 nm) into OPVs may be the result of light scattering off of the nanoparticles as opposed to near field effects. A thin layer of SiO₂ (<5 nm) on the other hand ensures that the nanoparticles remain electrically insulating but that the OPV material at the edge of the nanoparticle will experience an enhanced electromagnetic field due to the nanoparticle LSPR near field.

Incorporation of Nanomaterials into OPVs

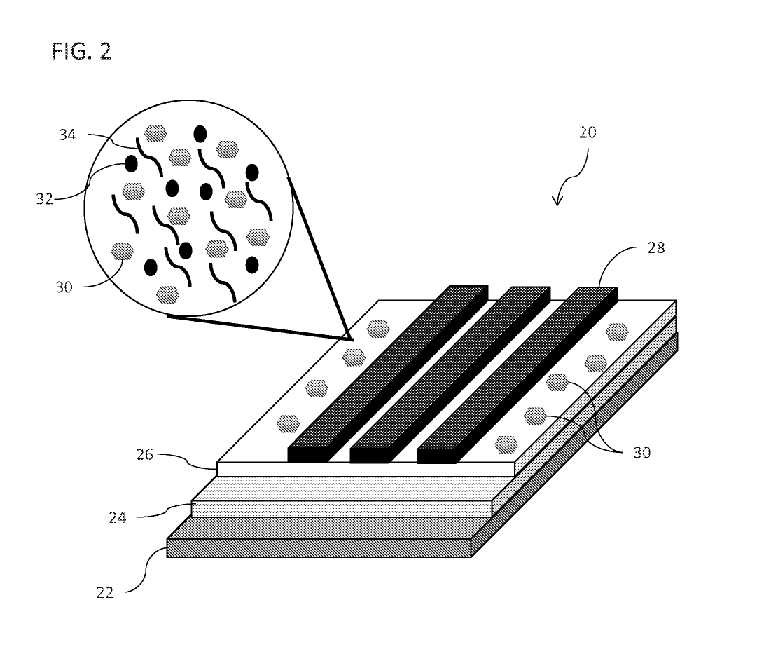

As described above, and shown in FIG. 2, an OPV (20) is a multilayer structure that uses a thin active layer (26) containing polymer materials (such as for example, PC₆₀BM) (32) and donor polymers (34), disposed atop substrate and insulating layers (22 & 24). In conventional OPVs, a significant portion of the incident photon flux remains unharvested; it also means that obtaining high light absorption efficiencies in OPV devices is crucial to making practical devices. Accordingly, in embodiments resonant light absorption and scattering materials (30) are inserted into the active layer (26) of the OPV. These materials are chosen to improve the high light absorption efficiencies of the OPV when disposed within the active layer of the OPV. There are several factors to consider in choosing appropriate resonant nanomaterials to improve the efficiency of the OPV.

In many embodiments, functionalization such as with an octadecyltrimethoxysilane (OTMS) organic ligand of the nanoparticles is performed in order to place the nanoparticles into solution with an OPV polymer-compatible solvent such as, for example, dichlorobenzene (DCB). It should be understood that any suitable solvent/ligand system may be used such that the nanostructures may be placed into solution with the active layer of the OPV. In some specific embodiments, short circuit current (J_{sc}) and photo conversion efficiency (PCE) of organic photovoltaic (OPV) polymer systems is accomplished by incorporating octadecyltrimethoxysilane (OTMS) functionalized gold/silica (Au/SiO₂) core/shell nanospheres and nanorods into the OPV active layers.

### Resonant Frequency of Resonant Nanomaterials

The frequency of light that is resonantly absorbed and scattered from the nanoparticle is another consideration in optimizing OPV device performance. Since different OPV polymers have different light absorption frequency bands, it is of interest to develop a light trapping technique that can be tailored to specific OPV polymers. In particular, in embodiments to maximize light trapping in practical applications, active layer-incorporated nanoparticles are spectrally tuned to match wavelength regions of poor light absorption. Understandably, in spectral regions where the OPV polymer absorbs light efficiently, the effect of incorporating plasmonic light trapping nanoparticles is small.

In order to tune these nanomaterials to the appropriate wavebands, an understanding of the optical properties of the materials is useful. The unique optical properties of Au nanoparticle colloid solutions arise from the interaction between light and the Au nanoparticle free electrons. The oscillating electromagnetic field of light periodically displaces electrons from their equilibrium positions in the positive metal ion lattice; at the same time, the positive ions in the metal lattice exert a restoring force on the electrons. If the electron cloud is confined in dimensions that are smaller than the wavelength of the incident light (as in the case of a nanoparticle), the light-resonant displacement of the electrons with respect to the positively charged lattice gives rise to a charge oscillation, termed the local surface plasmon resonance (LSPR). At the LSPR frequency, these resonant electron oscillations lead to strong light absorption and scattering in a fairly narrow wavelength range (˜100 nm full width half max). The absorbed light is generally dissipated as heat in electron-phonon collisions, while the scattered light is re-emitted into the environment at the same frequency as the incident light. (See, e.g., Chen, H., et al., Chemical Society Reviews, 2013, the disclosure of which is incorporated herein by reference.)

The LSPR oscillation frequency depends on the dielectric permittivity, the geometry of the nanoparticle and the dielectric permittivity of the medium. (See, e.g., Lee, K.-S. and M. A. El-Sayed, The Journal of Physical Chemistry B, 2005. 109(43): 20331-20338, the disclosure of which is incorporated herein by reference.) Lower LSPR frequencies result when the electron gas is confined in larger nanoparticle geometries, while higher LSPR frequencies are the result of confinement of the electron gas in smaller nanoparticle geometries. For example, colloids of Au nanorods of diameter 15 nm and length 30 nm exhibit peak light absorption and scattering at wavelengths of ˜620 nm, while Au nanorods of diameter 15 nm and length 60 nm exhibit peak absorption and scattering at wavelengths of ˜800 nm. Since spectrophotometers typically measure the sum of the absorption and scattering intensities of a nanoparticle colloid, it is common to refer to the sum of absorption and scattering as extinction. The relative contributions of absorption versus scattering depend on the nanoparticle geometry. Smaller nanoparticles (<30 nm) generally absorb the majority of incident light while larger nanoparticles (>30 nm) scatter a greater portion of the incident light. Spherical particles tend to absorb a larger proportion of light than ellipsoidal or rod-shaped nanoparticles. (See, e.g., El-Sayed, M. A., Accounts of Chemical Research, (2001). 34(4): 257-264, the disclosure of which is incorporated herein by reference.) Besides resonantly enhanced extinction, resonant electron oscillations at the LSPR frequency also lead to a highly enhanced electromagnetic field in the vicinity of the metal nanoparticle, termed the near field. The near field increases the probability of electronic transitions from the d band to the sp band in Au, generating electron-hole pairs whose subsequent recombination results in luminescence.

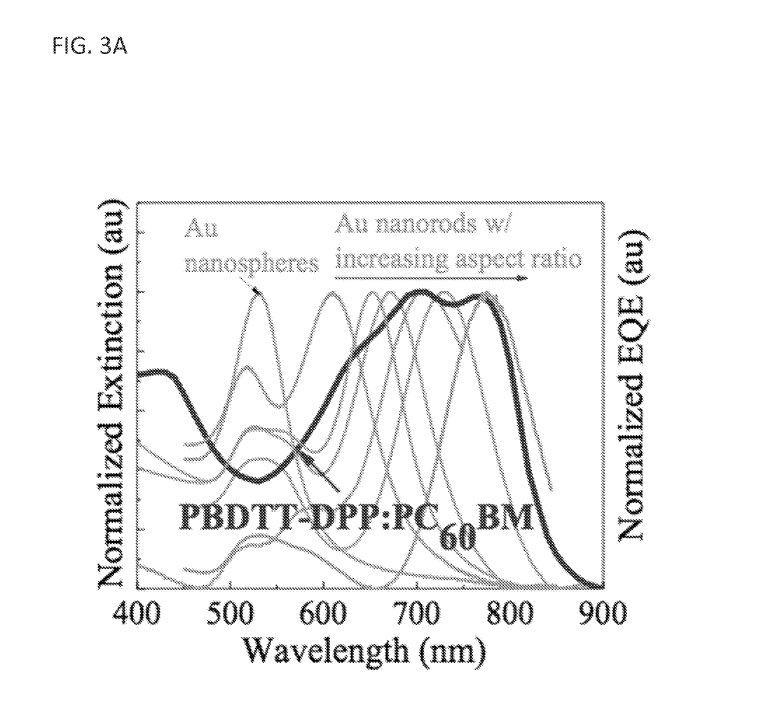

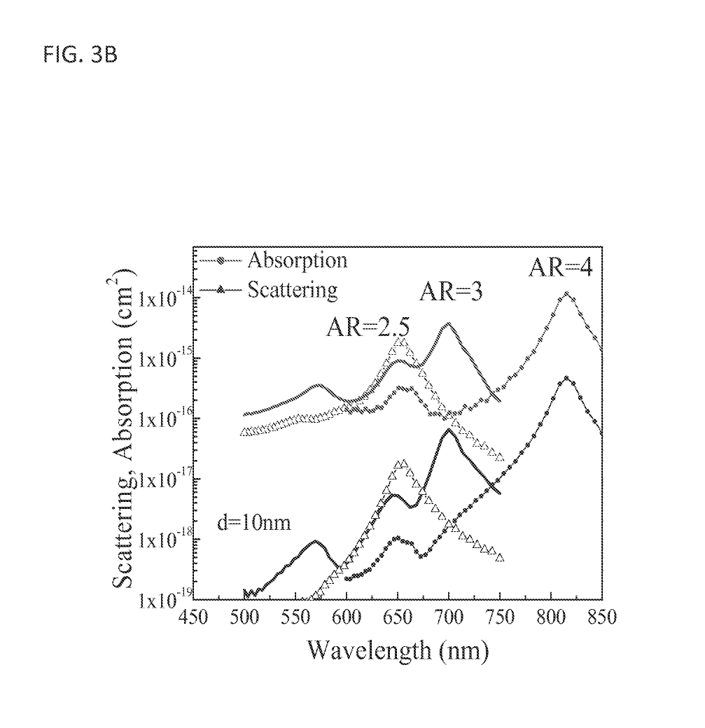

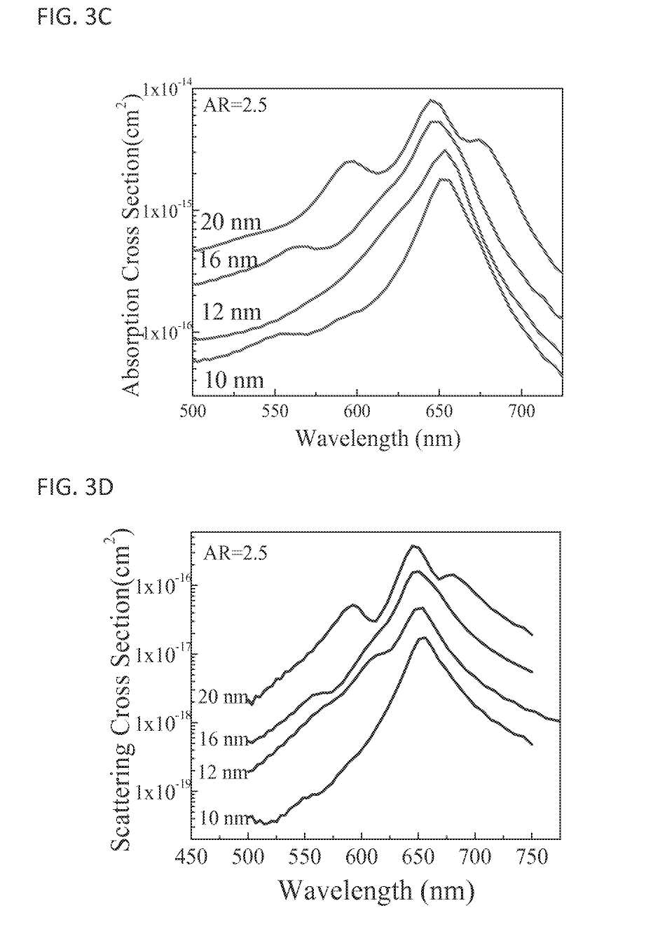

As discussed above, noble metal nanospheres have fairly narrow extinction wavelength bands. In non-symmetric noble metal nanostructures (such as, for example, nanorods), on the other hand, free electrons oscillate along both the long and short axes of the rod, resulting in two resonance bands: a band of wavelengths resulting from electron oscillations along the long axis, which, depending on the nanorod aspect ratio (A/R) ranges between ˜600 nm to ˜900 nm, and, a second, weaker band at ˜520 nm resulting from electron oscillations along the short axis (FIG. 3A). (See, e.g., Huang, X., et al., Nanomedicine, 2007. 2(5): p. 681-693, the disclosure of which is incorporated herein by reference.)

Using this A/R wavelength dependence it is thus possible to tune the LSPR near field enhancement wavelength band as needed. For example, FIG. 3B shows simulated absorption and scattering cross section spectra for Au/SiO₂ core/shell ellipsoids of varying aspect ratios. The transverse diameter of the Au ellipsoid was the same in each simulation (10 nm), while the longitudinal diameter was varied from 20 nm to 40 nm yielding ellipsoids of aspect ratios from 2 to 4 with resonance wavelengths from 650 nm to 800 nm. The SiO₂ shell was 5 nm thick in each simulation. These simulations indicate that one consideration in the design of Au/SiO₂ and Au/SiO₂/RE:Y₂O₃ core/shell nanorods is the aspect ratio (A/R) since it dictates the peak plasmon resonance.

While the nanorod aspect ratio determines the peak wavelength, as shown in FIGS. 3C and 3C, the Au nanorod size determines the absorption and scattering cross sections. In general, larger Au nanorods have higher absorption and scattering cross sections than smaller ones. According to simulation results, an Au nanorod with a 20 nm diameter and 50 nm length has absorption and scattering cross sections that are approximately an order of magnitude higher than those of an Au nanorod with a 10 nm diameter and 25 nm length (FIG. 3C). For light trapping applications, high light scattering cross sections are desirable but the disruption of OPV active layer morphology has to be taken into account in the design.

Accordingly, in embodiments, noble metal nanostructures of different A/Rs (and hence different peak extinction wavelengths) are disposed within OPV active layers to achieve LSPR near field absorption enhancements over a large range of wavelengths, as shown in the data plots provided in FIGS. 3A and 3B. Alternatively, in many embodiments nanostructures are selected that have LSPR near field absorption enhancement in spectral regions where the OPV polymer absorbs light least efficiently.

### Optically Active Nanomaterials

Although the above discussion has focused on core/shell plasmonic nanomaterials having a single core and single shell, in many embodiments the core/shell material may include more than one shell layer. In some such embodiments, this outer shell includes a material that is optically active at the same wavelength as the peak extinction (LSPR) of the plasmonic (noble metal) nanoparticle, forming a resonant plasmonic/photoluminescent structure. Such a combination of multiple shell layers results in a hybrid structure having an increased optical response compared to each of the component elements.

For example, in embodiments where the core/shell is formed of Au/SiO₂, an another optically active shell of, for example, a rare earth like Yb:Er:Y₂O₃, may be utilized. Such resonant plasmonic/photoluminescent structures include the ability to spectrally tune the quantum emitter and core LSPR. Such spectrally tailored core/shell nanomaterials (such as, for example, Au/SiO₂/Yb:Er:Y₂O₃) have the potential to further enhance OPV performance when used as additives in OPV active layers at the Au LSPR and rare earth quantum emitter light emission wavelengths compared to two-layer Au/SiO₂ core/shell nanomaterials, because in these spectrally tunable plasmonic/fluorescent nanomaterials the outer shell contains optically active materials that can set up a resonance with the Au plasmonic core and increase the optical response of the hybrid nanoparticle.

Au/SiO₂/Yb:Er:Y₂O₃ and Au/SiO₂/Yb:Tm:Y₂O₃ core/shell nanorod embodiments may be formed, for example, in which the Au nanorod extinction peak is spectrally matched to the emission peaks of the Er³⁺ and Tm³⁺ rare earths and the ions are placed in the nanorod near field region have not been demonstrated. In exemplary embodiments, to spectrally match the 655 nm Er3+ energy transition (4F9/2→4I15/2), Au nanorods of aspect ratio ˜2.5 are used, while in order to match the 800 nm Tm3+ energy transition (3H4→3H6), Au nanorods of aspect ratio ˜4 are used. In order to maximize the energy transfer between the plasmonic and fluorescent components of the hybrid core/shell nanoparticle, the silica spacer layer is configured be thin and between 0.5 nm and 2 nm.

It will also be understood that the compositions of the rare earths may also be selected to improve the optical properties of the core/shell nanomaterials. For example, Yb3+, Er3+ and Tm3+ ion compositions that result in the highest emission intensities depend on the host material. Jing et. al determined that the optimal concentration of Tm3+ is about 1 at % for a Yb3+ concentration of 10 at % for the blue upconverted emission using 980 nm excitation in Yb:Tm:NaY(WO4)2. (See, e.g., Jing, S., et al., Journal of Physics D: Applied Physics, 2006. 39(10): 2094, the disclosure of which is incorporated herein by reference.) Tikhomirov et. al. found that the most intense green emission band at 545 nm was observed for a 3:1 Yb:Er ratio in oxyfluoride glasses ((SiO2)9(AlO1.5)32(CdF2)22(PbF2)4.0(ZnF2):x(ErF3):z(YbF3)) where x and z were varied in the study to determine the optimum ratio. In their study, they found that when the total content of Er3+ and Yb3+ dopants increased up to 10 and more mol %, the intensity of upconversion luminescence bands decreased substantially. (See, e.g., Tikhomirov, V. K., et al., Solar Energy Materials and Solar Cells, 2012. 100(0): 209-215, the disclosure of which is incorporated herein by reference.) Melkumov et. al. found that the optimal Yb3+ concentration for lasing from phosphosilicate glasses was between 6-8 wt % and the optimal Er3+ concentration was between 0.1-0.4 wt %. (See, e.g., Melkumov, M. A., et al., Inorganic Materials, 2010. 46(3): 299-303, the disclosure of which is incorporated herein by reference.) Hirai et. al. synthesized Yb:Er:Y2O3 nanoparticles and found that the 662 nm emission peak reached a maximum intensity for an 8:1 Yb:Er ratio. (See, e.g., Hirai, T., et al., Chemistry of Materials, 2002. 14(8): 3576-3583, the disclosure of which is incorporated herein by reference.)

By tuning the LSPR of the core and optical activity of the rare earth shell it is possible to optimize the energy transfer between the plasmonic and the fluorescent component. When the LSPR frequency of the Au nanorod is tuned to a specific energy transition, it can increase its transition probability by providing a higher local density of photonic states and hence lead to higher emission rates or preferential emission from a specified frequency. Additionally, through energy transfer from the fluorescent ion to the plasmonic component, hybrid plasmonic/fluorescent nanorods may be able to achieve even higher efficiencies.

### Morphology and Concentration of Resonance Nanomaterial in Active Layer

Another consideration is the concentration, morphology and dispersion of the nanostructures within the OPV active layer. A sufficient concentration of the nanostructures needs to be included to ensure that there is sufficient resonance interaction leading to increased short circuit current and photo conversion efficiency in the OPV. However, the concentration needs to be maintained below a critical level above which the resonance nanomaterials begin to alter the active layer morphologies. In particular, the size and concentration of the embedded nanoparticles needs to be controlled to ensure that the morphology of the active layer is not disrupted. Similarly, in embodiments the degree to which the colloidal solutions are dispersed in the active layer may be controlled by preparing solutions with varying amounts of aggregated particles. For example, in embodiments the concentration and dispersion of the active layer-incorporated Au/SiO₂ core/shell nanoparticles is optimized. After a certain critical concentration, the addition of core/shell nanoparticles degrades device performance (as described in greater details below). The effect of a high concentration of Au/SiO₂ core/shell particles in the active layer may be the disruption of the OPV polymer morphology, potentially resulting in the lower carrier extraction.

### EXEMPLARY EMBODIMENTS

### Methods and Materials

### Nanoparticle Synthesis

The synthesis of Au nanospheres was achieved by reducing gold chloride (HAuCl₄) with sodium borohydride (NaBH₄) in the presence of a surfactant (cetyltrimethylammoniumbromide (CTAB)). To prepare 10.6 ml of Au nanospheres, 5 ml of a 0.5 mM HAuCl₄ solution were mixed with 5 ml of a 0.2M CTAB solution and then 0.6 ml of ice cold NaBH₄ was added to initiate the reaction. The protocol produces 2-5 nm diameter nanospheres which increased in size to ˜20 nm diameter nanospheres over a few days.

Synthesis of Au nanorods required preparation of two solutions: a seed solution and a growth solution. The seed solution was prepared by mixing 5 ml of 0.5 mM HAuCl₄, 5 ml of 0.2M CTAB and 0.6 ml of 0.1M ice cold NaBH₄. A solution of nanorods with a plasmon resonance of ˜650 nm was prepared using a growth solution that contained 0.6 ml of 0.01M AgNO₃, 20 ml of 0.5 mM HAuCl₄, 20 ml of 0.2M CTAB and 0.7 ml of 0.77 M ascorbic acid. To prepare nanorods with an extinction peak of ˜800 nm, 0.9 ml of 0.01 M AgNO₃ was used instead of 0.6 ml of 0.01 M AgNO₃ in the growth solution. The growth process was initiated by injecting 26 μl of seed solution into the growth solution at a temperature of 27° C. The reaction took approximately two hours to come to completion.

To coat the Au nanorods with SiO₂, a literature protocol developed by Pastoriza-Santos was followed. (See, e.g., Pastoriza-Santos, et al. Chemistry of Materials, 2006. 18(10): p. 2465-2467, the disclosure of which is incorporated herein by reference.) The nanorods were first rendered vitreophyllic by treating them with consecutive polyelectrolyte layers. Au metal has little affinity for SiO₂ because unlike most other metals, it does not form a passivating oxide film in solution. Furthermore, the CTAB stabilizing surfactant interferes with the SiO₂ coating process. In order to replace the CTAB stabilizer and modify the Au nanorod surface chemistry, consecutive polyelectrolyte layers were adsorbed onto the metal surface. This process proceeded in the following manner. First, the as-synthesized, CTAB-stabilized Au rods were centrifuged, the precipitate was redissolved in 3 ml of distilled water and then added to 3 ml of an aqueous solution containing poly-styrene sulfonate (PSS) (2 mg/mL and 6 mM NaCl) and stirred for approximately three hours. The PSS-modified particles were centrifuged twice to remove any excess PSS and redispersed in 3 ml of deionized water. The dispersion was then added drop-wise under vigorous stirring to 3 ml of an aqueous solution of poly(anilline hydrochloride) (PAH) of (2 mg/ml and 6 mM NaCl). PAH adsorption was allowed to proceed for three hours. The sample was then centrifuged to remove excess polyelectrolyte and redispersed in 3 mL of deionized water. Finally, 3 ml of the PSS/PAH functionalized Au spheres were added to a polyvinylpyrrolidone (PVP) solution (4 mg/ml). The mixture was stirred for approximately twelve hours, centrifuged to remove any excess polymer, and redispersed in 0.2 mL of deionized water. This aqueous dispersion of PVP-coated nanoparticles was then added drop-wise and under vigorous stirring to 2 mL of isopropyl-alcohol (IPA). Once the Au nanoparticles were transferred into IPA, SiO₂ coating was completed through the adjustment of the pH and addition of tertra-ethyl-orthosilicate (TEOS). The pH was adjusted to 10 by adding 1.5 ml, 4 vol % NH₃ in IPA (27% in water). Finally, 0.4 ml of TEOS (1 vol % in ethanol) was added under gentle stirring and the reaction was allowed to proceed for approximately twelve hours.

In order to dissolve the Au/SiO₂ core/shell nanorods in an OPV-compatible solvent, like dichlorobenzene, functionalization with octadecyltrimethoxysilane (OTMS) was performed. The Au/SiO₂ core/shell nanorods were centrifuged and redissolved in 3 ml of ethanol containing 30 μl of NH₄OH (32%). 300 μl of OTMS chloroform solution (3%) was added drop-wise with vigorous stirring and functionalization of the SiO₂ surface was achieved by hydrolysis of the methoxy groups and condensation of the resulting silane groups with SiOH groups on the SiO₂ surface. Transmission electron microscopy (TEM) using an FEI TF20 was used to confirm the morphology of the synthesized Au/SiO₂ core/shell nanorods, while UV Vis spectroscopy was used to determine the extinction spectra of the nanorod solutions.

To coat the Au/SiO₂ core/shell nanorods with a layer of rare earth doped yttria, a sol-gel method was utilized. Deposition of the Er₂O3 shell proceeded by creating a solution containing 5 mM urea while the mass of the RECl₃ salt is varied based on the desired shell thickness. The rare earth emitter doped yttria outer shell was deposited by adding the Au/SiO₂ core/shell nanorods prepared by using a growth solution containing chloride salts of the rare earth elements of interest in the desired concentration ratios. To determine the amount of YCl₃ salt needed to deposit conformal shells of Y₂O₃ the following formula in which the SiO₂ density is replaced with Y₂O₃ density is used:

$${m}_{TEOS} = {ρ}_{{SiO}_{2}} ( {V}_{\frac{Au}{{SiO}_{2}} n r} - {V}_{Aunr} ) ( \frac{{m}_{Au}}{{m}_{Au nr}} ) ( \frac{{MW}_{TEOS}}{{MW}_{{SIO}_{2}}} )$$

where: ρ_{SiO}_{₂} is the SiO₂ density (kg/m³), V_{Au/SiO}_{₂} ₙᵣ is the volume of 1 Au/SiO₂ core/shell nanorod (m³), V_{Au nr} is the volume of 1 Au nanorod (m³), MW_{SiO}_{₂} is the molecular weight of SiO₂ (kg/mol), MW_{TEOS} is the molecular weight of tetraethylorthosilicate (kg/mol), m_{Au} is the mass of Au precursor (kg), and m_{Au nr} is the mass of 1 Au nanorod (kg). Using this formula, the amounts of TmCl₃, ErCl₃ and YbCl₃ were determined from the desired ratio to the YCl₃ precursor. In order to achieve conformal coating, the mixture is stirred at 80° C. for 5 hours.

### Plasmonic OPV Device Fabrication

Polymer reference solutions consisted of 20 mg/mL of P3HT:PC₆₀BM (1:1 weight ratio) and 6 mg/mL PBDTT-DPP:PC₆₀BM (1:2.5 weight ratio). The plasmonic P3HT:PC₆₀BM solar cell device solution was prepared by adding a solution of the OTMS-functionalized Au/SiO₂ core/shell nanorods (AR˜2.5) to the P3HT:PC₆₀BM solution so that the final concentration of the nanorods was 0.6 mg/mL. The plasmonic PBDTT-DPP:PC₆₀BM solar cell device solution was prepared by mixing the OTMS-functionalized Au/SiO₂ core/shell nanorod solution (AR˜4) with the PBDTT-DPP:PC₆₀BM solution so that the final concentration of Au/SiO₂ core/shell nanorods was 0.2 mg/mL.

All the devices in this manuscript had the same structure: indium tin oxide (ITO)/poly(ethylenedioxythiophene):polystyrenesulphonate (PEDOT:PSS) (4083)/active layer/Calcium (Ca)/Aluminum (Al). The PEDOT:PSS was pre-coated onto the ITO substrate and baked at 120° C. for fifteen minutes before spin-casting the solutions. The P3HT:PC₆₀BM-based devices were spin-coated at 800 rpm for 40 seconds after which the wet films remained in the petri dishes until they dried (the color of the films changed from orange to dark-red). This solvent annealing process has been demonstrated to attain an optimized morphology for P3HT:PC₆₀BM-based organic solar cell devices. The PBDTT-DPP:PC₆₀BM-based devices were fabricated by spin-casting at 1800 rpm for 80 seconds with no other treatment. A bilayer cathode containing a Ca layer (20 nm) and a subsequent Al layer (100 nm) were deposited by thermal evaporation under high vacuum (<3*10⁻⁶ Torr). The active layer thickness of the P3HT:PC₆₀BM-based devices was ˜210 nm while the thickness of the PBDTT-DPP:PC₆₀BM-based devices was ˜90 nm. The thickness is measured by Vecoo Dektak 150 profiler.

### Transmission Electron Microscopy

Transmission electron microscopy (TEM) with energy dispersive spectroscopy was utilized to characterize Au nanorod geometry and aspect ratio of the synthesized Au nanorods. In TEM, a beam of electrons is transmitted through the specimen and an image is formed from the interaction of the electrons transmitted through the specimen; the image is magnified and focused onto an imaging device, such as a fluorescent screen or a charged coupled device (CCD) camera. High resolution transmission electron microscopy (HRTEM) is a method for imaging that can have resolution down to the atomic level. When used at the atomic scale, the crystal planes and growth direction can be easily calculated and indexed and can be used to determine the internal microstructure of the material. In this work, the TEM filament was excited by a high energy source and are accelerated by an electrostatic potential and focused onto a thin sample, no more than 200 nm, by a series of condenser lenses. Unlike an optical microscope, the condenser lenses do not focus the electrons based on curvature and index of refraction. A condenser lens uses a magnetic field to alter the path of the electron to converge through the thin sample and the image is projected onto a detector. To obtain diameter, size distribution and morphology information, Au nanorods were morphologically characterized using transmission electron microscopy (TEM, Tecnai 20; FEI Co., Eindhoven, Netherlands) at an acceleration voltage of 300 kV. To prepare the TEM samples, nanoparticles were diluted to a concentration of 1 mg/ml. Nanoparticle specimens for TEM were prepared by placing one drop of the diluted solution onto a carbon-coated copper grid, allowing it to dry at room temperature for 15 min.

### Optical Spectroscopy

Optical spectroscopy is an analytical technique that gives information about how a material interacts with light. The intensity of light passing through a sample (I) is compared to the intensity of light before it passes through the sample (Io) over a range of wavelengths. The ratio I/Io provides information about the spectral characteristics of electron energy transitions in the sample.

The basic parts of a spectrophotometer are a light source, a sample holder, a diffraction grating and a photodetector. In this study, the absorption spectrum is collected using a Shimadzu UV-3101PC with a measurement range between 190-3100 nm. The system has two excitation sources, a tungsten lamp and a deuterium lamp. The tungsten lamp is the primary excitation source since measurements occur outside of the deuterium range (>290 nm). Additionally, two types of detectors are used based on the measurement wavelength, with an InGaAs detector for wavelengths between 850-3100 nm and a Si detector for 290-850 nm. The probing energy is selected using a dual monochromator system with a resolution of 0.1 nm.

### Photoluminescence Spectroscopy

Photoluminescence (PL) spectroscopy is a contactless, nondestructive method of probing the electronic structure of material. In PL spectroscopy, light directed onto a sample imparts energy onto the material and causes electrons within a material to move into excited states. When these electrons return to their equilibrium states, the excess energy is released in radiative processes (light emission), or it is dissipated in nonradiative processes. In nonradiative relaxation, the energy is released as phonons. Nonradiative relaxation occurs when the energy difference between the levels is very small and typically occurs much faster than a radiative transition. Large nonradiative transitions do not occur frequently because the crystal structure generally cannot support large vibrations without destroying bonds. Meta-stable states form a very important feature that is exploited in the construction of lasers. Specifically, since electrons decay slowly from them, they can be populated at this state without too much loss and then stimulated emission can be used to increase an optical signal.

The energy of the emitted light is related to the difference in energy levels between the two electron states involved in the transition between the excited state and the equilibrium state, while the intensity of the emitted light is related to the relative contribution of the radiative process compared to nonradiative energy transitions. Sample excitation can be achieved with either a broadband, non-coherent light source like a lamp or a narrow band, coherent light source such as a laser. The excitation frequency can either be higher than the frequency of the emitted light in which case the PL is termed downconversion (since higher energy light is converted into lower energy light), or it can be lower than the emitted light, in which case the process is termed upconversion (since two or more photons of lower energy lead to the emission of a photon of higher energy). The experimental setup used was a light from a fiber-coupled 980 nm laser diode (Sheaumann) was focused onto a sample. The upconverted light emitted from the sample passed through a 980 nm optical filter to remove scattered excitation light and was then focused onto a monochromator (Orion Cornerstone 260) that separated the emitted light into its constituent wavelengths. A Si photodetector (SpectraPhysics S890) was used to measure the intensity of the upconverted light as a function of wavelength.

### Radiative Lifetime

The rate of light emission of a photo-excited species depends on the internal structure of the light emitter and the density of electromagnetic modes of the local environment around the emitter. Purcell showed that a high electromagnetic mode density increases the spontaneous emission rate of light emitters and this fact has been utilized to increase the brightness of emitter by placing them in resonant optical cavities, photonic crystals or in the enhanced electromagnetic field that exists in the vicinity of plasmonic nanoparticles (1946; Rogobete 2007). This study compared the radiative liftetimes of Er3+ ions located in the near field of an Au nanorod (in which the emitter experiences an enhanced local electromagnetic field) with that of an Er3+ ion in an unperturbed electromagnetic environment.

Lifetime measurements were performed using a time-resolved fluorescence spectrometer (Edinburgh FLS920) with a nanosecond nitrogen filled flash-lamp, Czerny-Turner monochromator and a Si CCD detector. Radiative lifetimes were collected using the time correlated single photon counting (TCSPC) method with a 5000 photon minimum count. In TCSPC the sample is repetitively excited using a pulsed light source and the measurement builds a probability histogram relating the time between an excitation pulse and the observation of the first fluorescence photon. Samples were excited at 520 nm with a slit size of 5 nm and the lifetime emission was collected at 564 nm with 10 nm slits.

### External Quantum Efficiency

External quantum efficiency (EQE) measurements quantify the spectral response of a solar cell device by measuring device photocurrent as a function of wavelength. This work investigated the spectral response of organic photovoltaic (OPV) devices with and without plasmonic light trapping (PLT) Au/SiO₂ core/shell nanorods incorporated in the OPV device active layer. Light from a 50 W arc lamp was focused onto the entrance slit of an Orion Cornerstone 260 monochromator controlled with a USB port. A solar cell with its terminals connected to an optical power meter was attached to the exit slit of the mononchromator. EQE spectra were collected using Traq32 software.

### Example 1

### Characterization of EQE of OPVs

In order to study the viability of the resonant nanomaterials, Au/SiO₂ core/shell nanospheres and nanorods were incorporated into the active layers of two polymer OPV systems: P3HT:PC₆₀BM and PBDTT-DPP:PC₆₀BM. It was hypothesized that the greatest enhancement due to the LSPR near field would be observed in embodiments where the resonance of the materials fell in the spectral regions where the OPV polymer absorbs poorly, and the lowest enhancement would be observed in spectral regions where the OPV polymer absorbs efficiently.

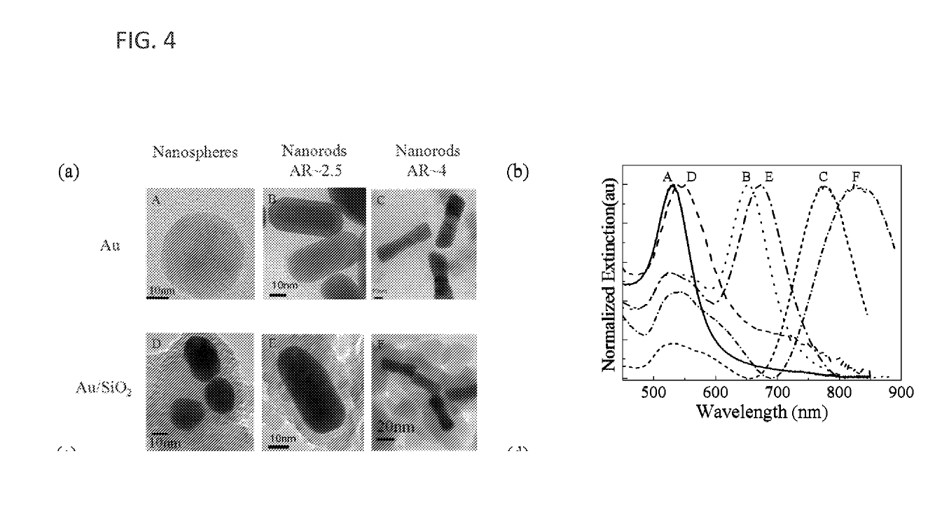

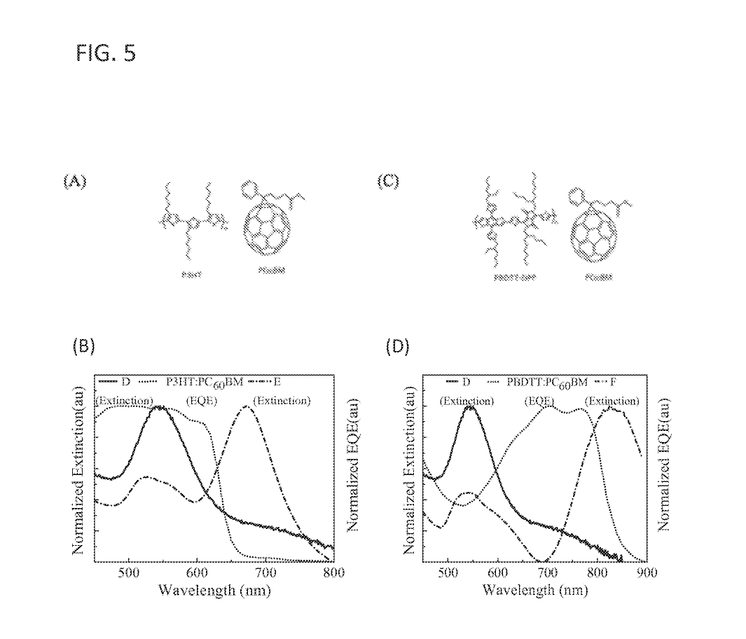

To investigate this hypothesis, EQE measurements on OPV devices with spectrally-tuned Au/SiO₂ nanoparticles were performed. For the P3HT:PC₆₀BM system, Au/SiO₂ nanospheres with a peak extinction of ˜540 nm (matching a spectral region of high polymer absorption) and AR˜2.5 Au/SiO₂ nanorods with a peak extinction of ˜670 nm (matching a spectral region of poor polymer absorption at the band edge of the P3HT:PC₆₀BM) were synthesized. For the PBDTT-DPP:PC₆₀BM system, Au/SiO₂ nanospheres with a peak extinction of ˜540 nm (matching a spectral region of moderate polymer absorption) and AR˜4 Au/SiO₂ nanorods with a peak extinction of ˜830 nm (matching a spectral region of poor polymer absorption) were synthesized. The SiO₂ shell thickness in all samples was ˜10 nm. Error! Reference source not found. FIG. 4 shows the transmission electron microscopy (TEM) images (FIG. 4A) and corresponding extinction spectra (FIG. 4B) of the Au and Au/SiO₂ core/shell nanosphere and nanorod colloidal solutions, while FIGS. 5A and 5B show the chemical structures and the normalized EQE spectra of the two OPV polymer systems as well as the extinction spectra of the Au/SiO₂ colloidal solutions used in this study. Using these plots it is possible to determine the A/R and other properties of the core/shell nanoparticle necessary to match the LSPR of the core to the OPV polymer system to allow maximum efficiency improvement.

### Example 2

### Optimizing Nanoparticle Effect on OPV Device Performance

Short circuit current (J_{sc}), open circuit voltage (V_{oc}), and external quantum efficiency (EQE) measurements were performed on OPV devices. Blending the Au/SiO₂ nanospheres and nanorods in the BHJ resulted in an enhanced J_{sc} and PCE in both the P3HT:PC₆₀BM and PBDTT-DPP:PC₆₀BM devices compared to the reference devices. Two key parameters were then investigated: 1) the effect of the concentration of the active layer-incorporated Au/SiO₂ nanoparticles, and 2) the effect of the extinction peak wavelength of the active layer-incorporated Au/SiO₂ nanoparticles on OPV device performance.

### Concentration Study

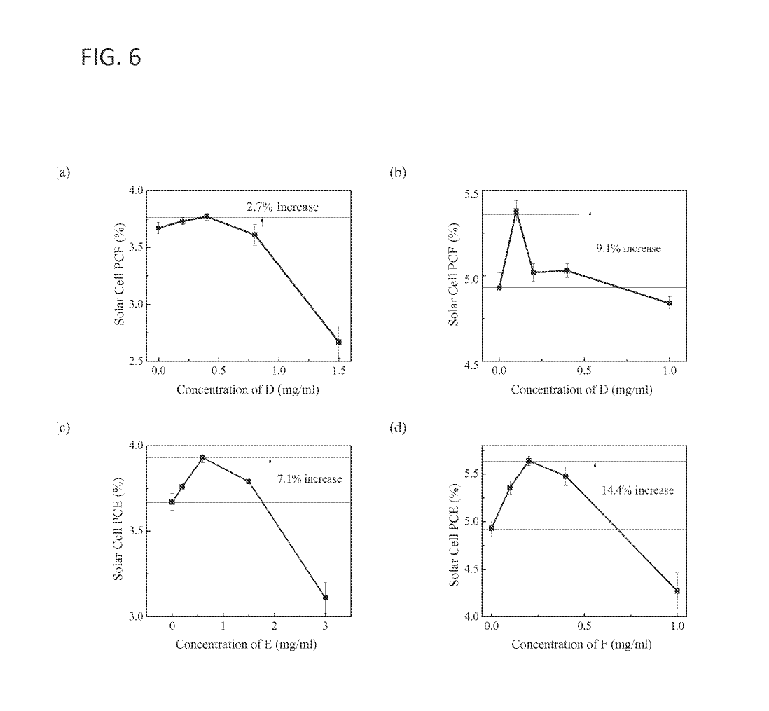

A concentration study was conducted and revealed that OPV device performance depended sensitively on the amount of Au/SiO₂ core/shell nanospheres or nanorods incorporated into the active layer. Increasing the amount of Au/SiO₂ nanoparticles led to an initial increase in solar cell PCE. As the Au/SiO₂ concentration increased, however, a drop in device performance was observed. For the P3HT:PC₆₀BM system, the optimal Au/SiO₂ nanosphere concentration was 0.4 mg/ml and 0.6 mg/ml for the Au/SiO₂ nanorods; concentrations of nanospheres or nanorods greater than 2 mg/ml resulted in OPV device performance degradation. As shown in FIG. 6A to 6D, the optimum Au/SiO₂ core/shell nanosphere concentration for the PBDTT-DPP:PC₆₀BM system was 0.1 mg/ml and 0.2 mg/ml for the Au/SiO₂ nanorods (AR˜4); concentrations of either nanospheres or nanorods greater than 1 mg/ml resulted in OPV device performance degradation. These results are also summarized in Tables 1 to 4.

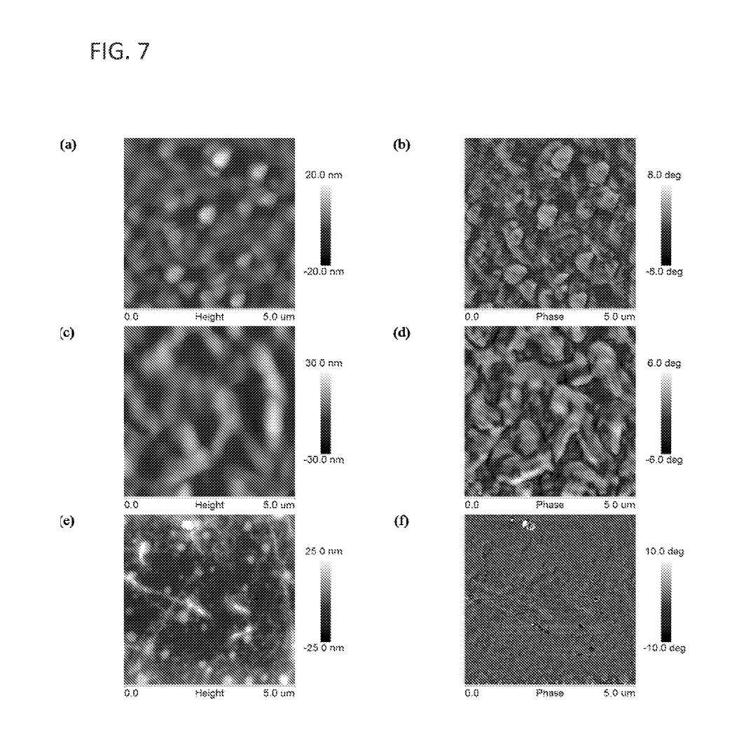

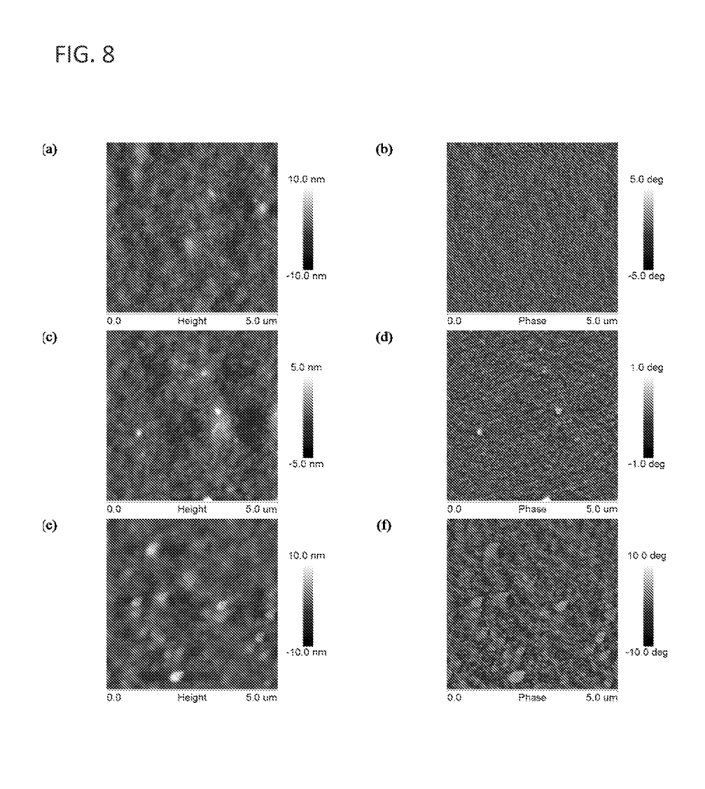

The poor performance of the low concentration is a function of insufficient resonance field and low carrier extraction. The result at higher concentrations requires more explanation. A possible reason for the observed trends is that with increasing Au/SiO₂ core/shell nanoparticle concentration, the OPV cell morphology is disturbed and may lead to lower carrier extraction. The lower optimal concentration of Au/SiO₂ nanospheres compared to Au/SiO₂ nanorods in both systems was attributed to the fact that the as-synthesized Au/SiO₂ sphere colloidal solutions were dispersed less uniformly and contained more aggregates of Au/SiO₂ nanospheres than the Au/SiO₂ nanorod colloids (determined from visual inspection of the colloid solutions and AFM images, see FIGS. 7A to 7F and 8A to 8F). The BHJ morphology evolution with different amounts of Au/SiO₂ nanoparticles is a critical factor affecting the overall device performance, e.g. the Au/SiO₂ nanoparticles might alter the crystallinity, molecular packing and donor/acceptor interface. Hence, the less well dispersed Au/SiO₂ core/shell nanosphere colloids may have disturbed the OPV cell morphology to a greater extent.

### Nanoparticle Extinction Frequency on OPV Device Performance

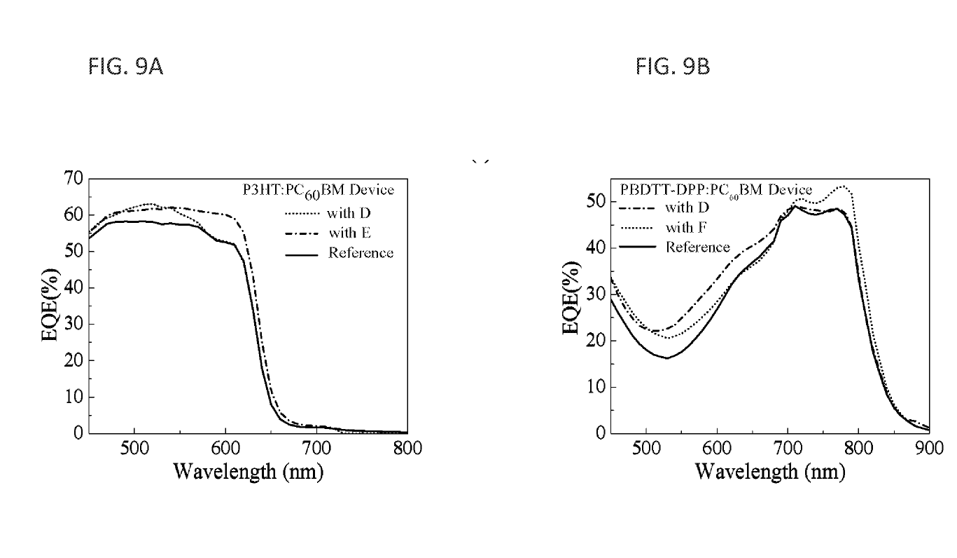

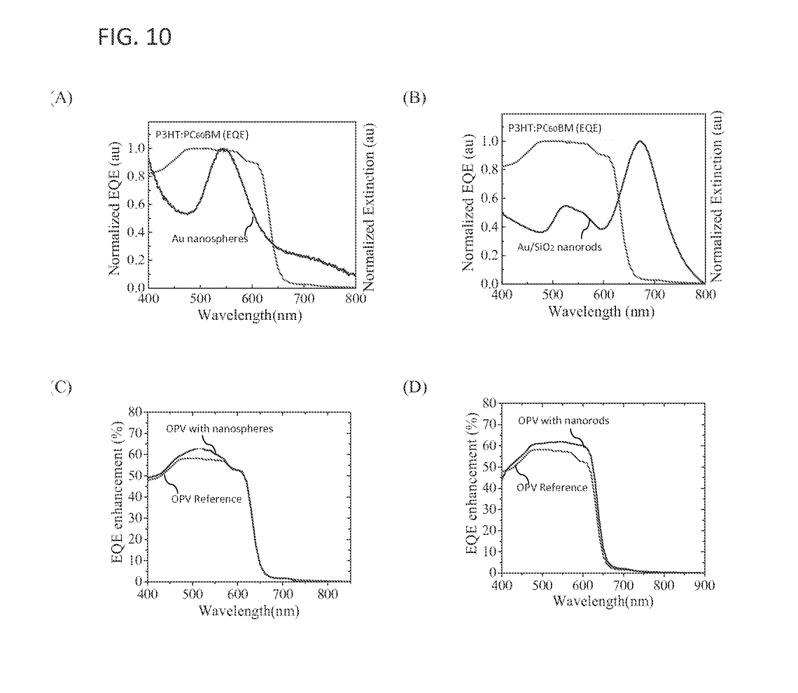

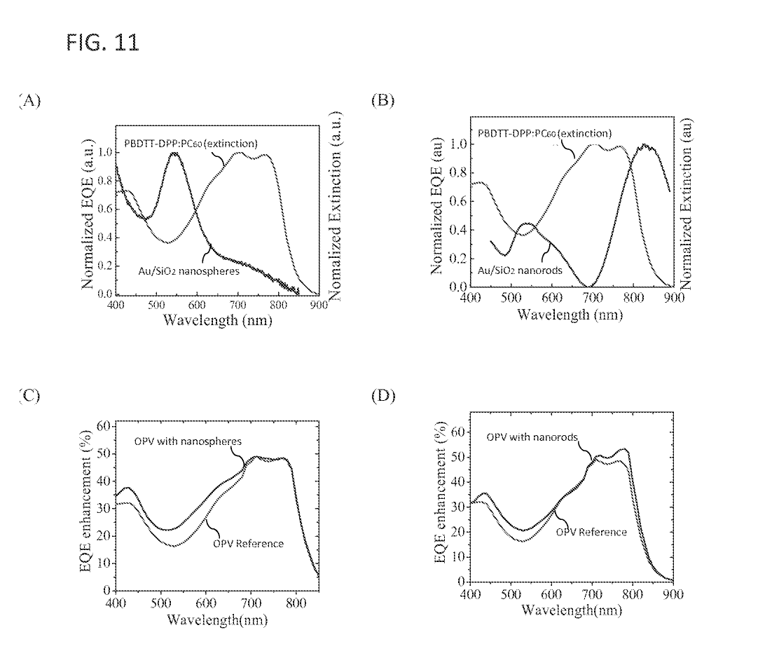

Besides optimizing the concentration of the active layer-embedded core/shell nanoparticles, optimizing the peak extinction frequencies of the Au/SiO₂ nanoparticles is also important in order to tailor and maximize light trapping in the OPV. Reference and plasmonic OPV device EQE spectra were measured for both the P3HT:PC₆₀BM and the PBDTT-DPP:PC₆₀BM systems. In order to obtain EQE enhancements, the reference EQE spectra were subtracted from the plasmonic OPV device EQE spectra. FIGS. 9A and 9B show EQE enhancements of OPV devices plotted with the extinction spectra of Au/SiO₂ nanospheres and nanorods embedded in their active layers. The EQEs of the plasmonic and reference OPV devices are shown in FIGS. 10A-10D and 11A-11D.

EQE enhancements in both polymer systems spectrally matched the extinction spectra of the active layer incorporated Au/SiO₂ core/shell nanospheres and nanorods. This indicates that the narrow band LSPR near field is playing a role in the efficiency enhancements observed since pure light scattering would manifest as a broadband EQE enhancement. AR˜4 Au/SiO₂ core/shell nanorods with extinction peaks matched to the band edges of the PBDTT-DPP:PC₆₀BM OPV systems showed the highest EQE enhancement factors while Au/SiO₂ nanospheres incorporated in a P3HT:PC₆₀BM system showed the lowest performance enhancement. The mismatch between the EQE of the P3HT:PC₆₀BM polymer system and the extinction spectrum of the Au/SiO₂ nanospheres indicate that in some embodiments plasmonic enhancement should target spectral regions where the OPV cell absorbs poorly (for example near the band edge). The results of the best devices for both systems are summarized in Table 5, below.

TABLE 5
SOLUTION CONCENTRATIONS AND DEVICE
PERFORMANCE RESULTS.

| | | J_{sc} | V_{oc} | FF | PCE |
|---|---|---|---|---|---|
| POLYMER SYSTEM | DEVICE | (mA/cm²) | (V) | (%) | (%) |
| P3HT:PC₆₀BM | Reference | 9.04 | 0.605 | 68.0 | 3.72 |
| 20 mg/ml | Plasmonic | 9.84 | 0.600 | 66.9 | 3.95 |
| (1:1 wt ratio) | (0.6 mg/ml | | | | |
| | Au/SiO₂) | | | | |
| PBDTT-DPP:PC₆₀BM | Reference | 10.43 | 0.750 | 64.2 | 5.02 |
| 6 mg/ml | Plasmonic | 12.31 | 0.750 | 61.6 | 5.69 |
| (1:2.5 wt ratio) | (0.2 mg/ml | | | | |
| | Au/SiO₂) | | | | |

For the P3HT:PC₆₀BM system, the J_{sc} was improved by 8% while for the PBDTT-DPP:PC₆₀BM system, the improvement was 16%. The V_{oc} were nearly the same for both systems, while the fill factor (FF) decreased 1.1% for the P3HT:PC₆₀BM system and 2.6% for PBDTT-DPP:PC₆₀BM system. This may be attributed to the fact that the morphology of the device was altered after incorporation of the Au/SiO₂ nanorods.

In the low band gap polymer system, PBDTT-DPP:PC₆₀BM, a larger enhancement was observed than in the P3HT:PC₆₀BM system. From the EQE enhancement factor, it was found that the improvement was in two spectral regions: one at ˜830 nm that matched the longitudinal oscillation mode of the Au/SiO₂ nanorods, and another one at ˜540 nm that matched the transverse oscillation mode of the Au/SiO₂ nanorods. The results indicate that spectral tuning of the active layer plasmonic light-trapping particles is an important consideration for active layer incorporated plasmonic light trapping in OPVs.

For light trapping applications, ideal Au/SiO₂ core/shell nanorods should have light scattering peaks resonant at OPV band edges and be incorporated into the OPV polymer active layer. For the P3HT:PC₆₀BM polymer with a band edge of ˜670 nm, the addition of the core/shell nanorods with an aspect ratio (AR) ˜2.5 should result in an improvement in photon conversion efficiency (PCE), while for the PBDTT-DPP:PC₆₀BM polymer with a band edge of ˜830 nm, the addition of core/shell nanorods of AR˜4 result in an improvement in PCE.

### Example 3

### Spectrally Tunable OPV Devices

Spectrally tailored Au/SiO₂/Yb:Er:Y₂O₃ core/shell nanomaterials, such as nanorods have the potential to further enhance OPV performance when used as additives in OPV active layers at the Au LSPR and rare earth quantum emitter light emission wavelengths compared to Au/SiO₂ core/shell nanorods. This is because in Au/SiO₂/Yb:Er:Y₂O₃ core/shell nanorods, the outer shell contains optically active materials which can set up a resonance with the Au plasmonic core and increase the optical response of the hybrid nanoparticle. In some embodiments, such Au/SiO₂/Yb:Er:Y₂O₃ core/shell nanorods were formed and the emission and power responses tested.

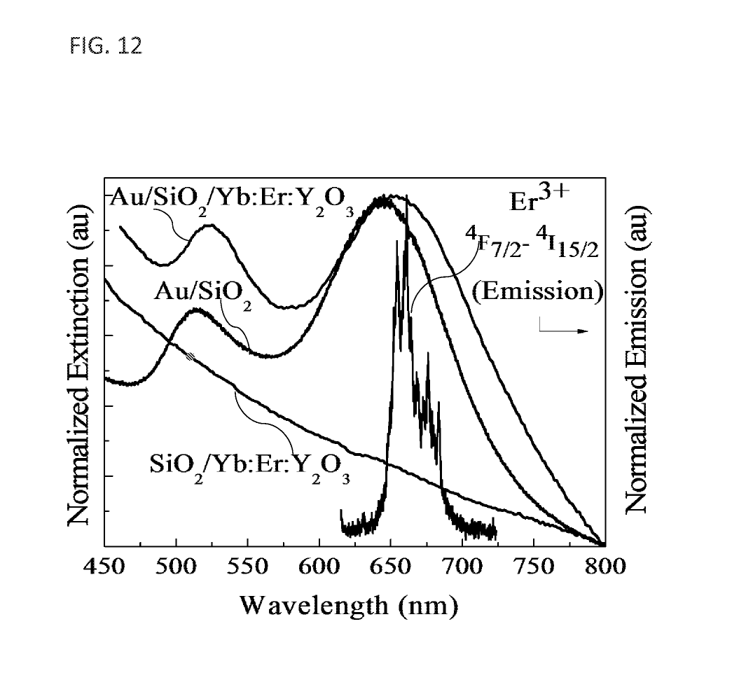

FIG. 12 shows a UV-Vis absorption spectra of Au/spectra for solutions of Au/SiO₂/Yb:Er:Y₂O₃, SiO₂/Yb:Er:Y₂O₃ and Au/SiO₂ nanomaterials along with emission spectrum associated with the Er^{3+ 4}F9/2→⁴I15/2 radiative energy transition. The aspect ratio of the Au nanorod is selected so that the Au nanorod LSPR frequency matches the frequency of the Er^{3+ 4}F9/2→⁴I15/2 radiative energy transition. This is done so as to maximize the optical response of the core/shell nanostructures through resonant energy transfer between the plasmonic material (Au) and the photoluminescent material (rare earth doped yttria in this case).

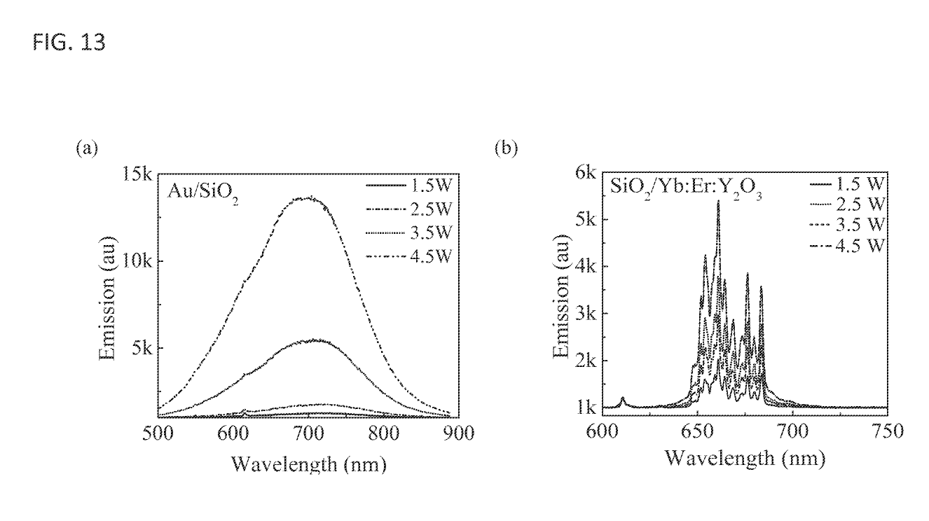

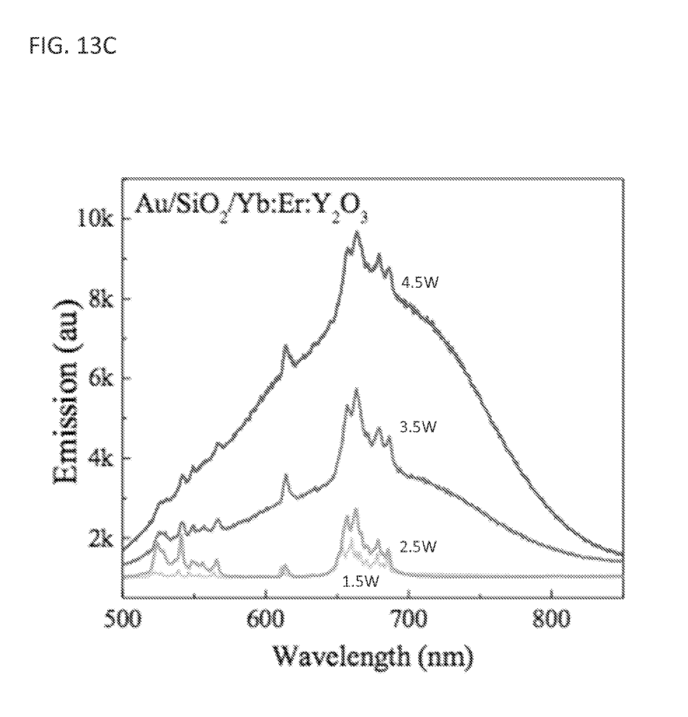

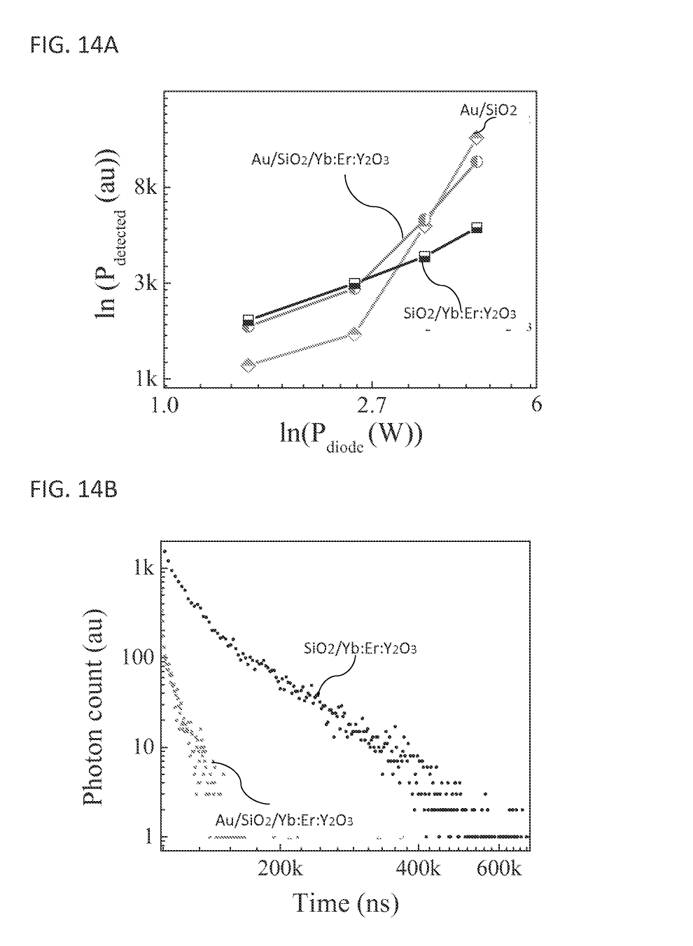

The upconversion PL intensity versus pump power relationship was probed to determine the statistical photon requirement (n) for the upconversion from 980 nm excitation wavelength to the 660 nm emission wavelength for Au/SiO₂ (FIG. 13A), SiO₂/Yb:Er:Y₂O₃ (FIG. 13B), and Au/SiO₂/Yb:Er:Y₂O₃ (FIG. 13C). The PL intensity of the SiO₂/Yb:Er:Y₂O₃ scaled linearly with pump power. The PL intensity versus excitation log-log slope of 1.4 indicates a multi-photon upconversion process. The Au/SiO₂ and Au/SiO₂/Yb:Er:Y₂O₃ core/shell nanorods on the other hand displayed non-linear optical characteristics with increasing excitation power. The logarithmic peak PL emission intensity as a function of excitation power for Au/SiO₂/Yb:Er:Y₂O₃ and SiO₂/Yb:Er:Y₂O₃ are shown in FIG. 14A. The radiative lifetime measurements for the Er^{3+ 4}F9/2→⁴I15/2 energy transition in samples Au/SiO₂/Yb:Er:Y₂O₃ and SiO₂/Yb:Er:Y₂O₃ are shown in FIG. 14B. These data results demonstrate that these spectrally tailored Au/SiO₂/Yb:Er:Y₂O₃ core/shell nanomaterials, have the potential to further enhance OPV performance when used as additives in OPV active layers at the Au LSPR and rare earth quantum emitter light.

### Comparison of Simulations

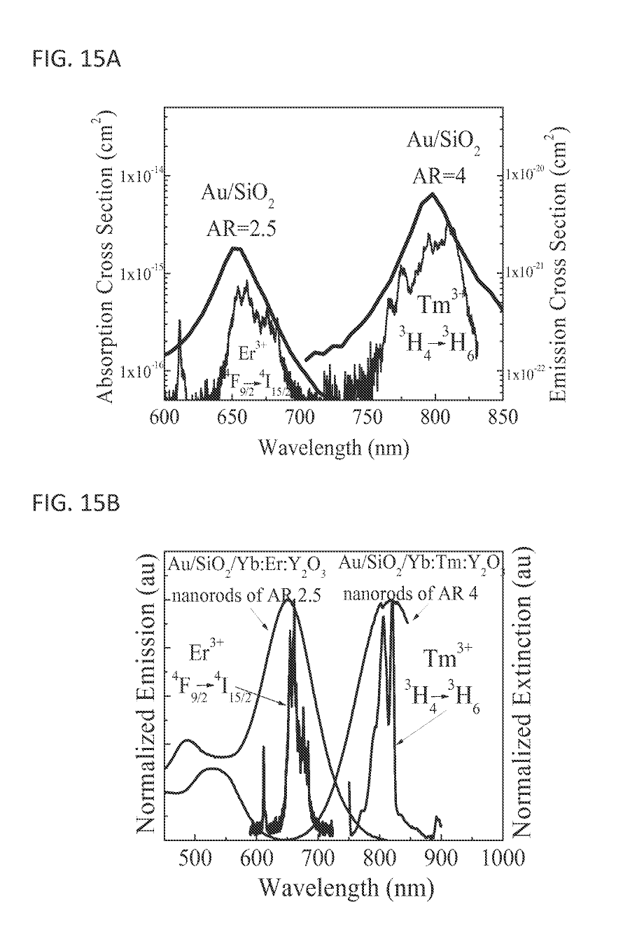

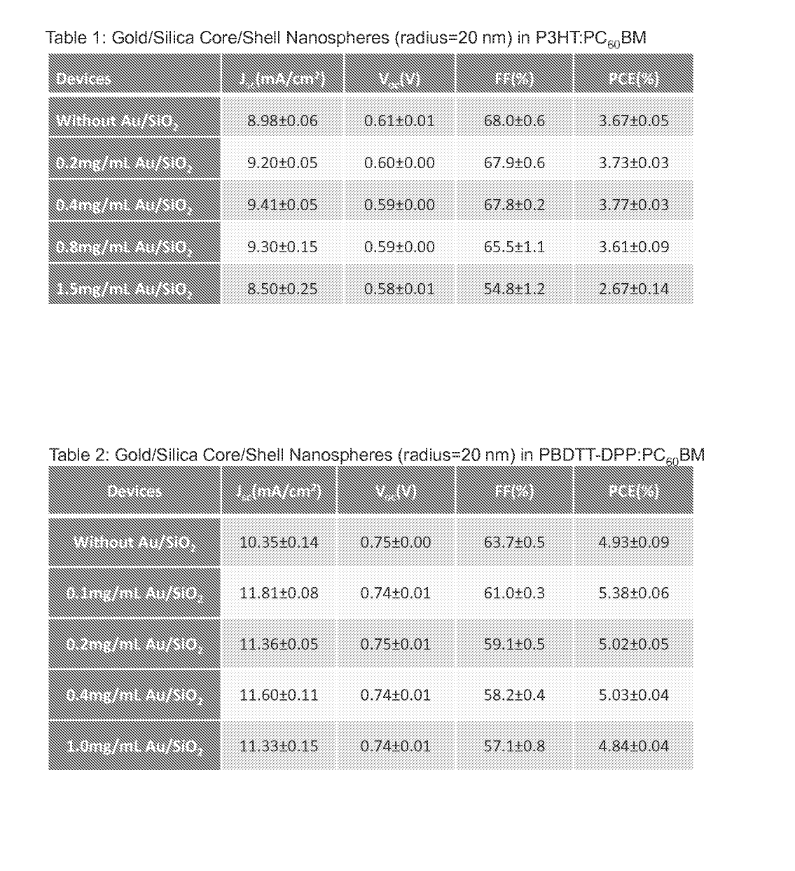

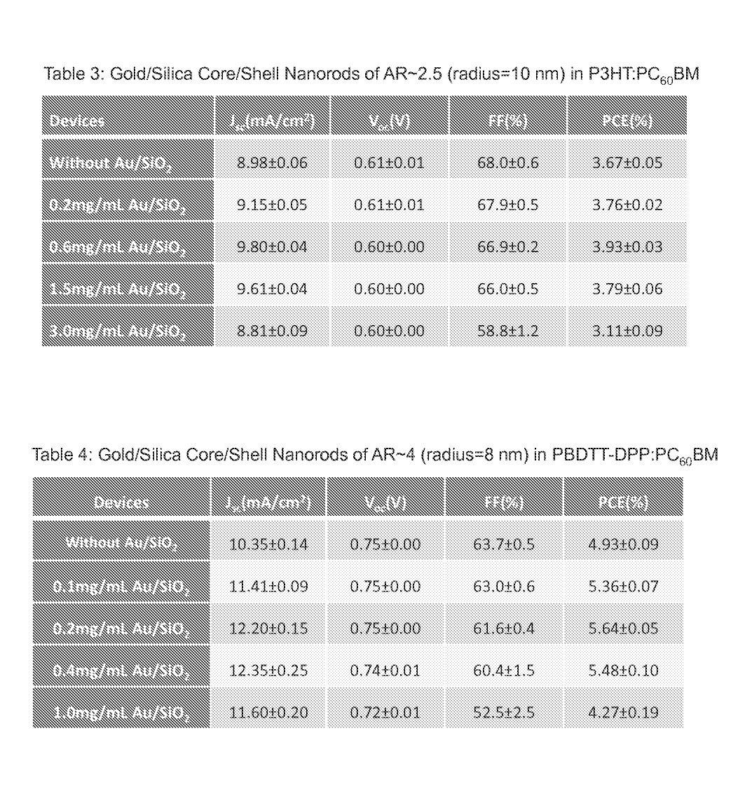

FIG. 15A shows simulated absorption cross sections of Au/SiO₂ core/shell nanorods of 12 nm diameter, 30 nm length, 10 nm thick SiO₂ shell (12×30, 10 nm), Au/SiO₂ core/shell nanorods of 10 nm diameter, 40 nm length with a 5 nm thick SiO₂ shell (10×25, 5 nm) and experimental emission cross section spectra of the 4F9/2→4I15/2 energy transition of Er³⁺ (˜655 nm) and the 3H4→3H6 energy transition of Tm³+(˜805 nm). Simulations indicate that one important consideration in the design of Au/SiO₂ and Au/SiO₂/RE:Y₂O₃ core/shell nanorods is the aspect ratio (AR) since it dictates the peak plasmon resonance. In some embodiments, in order to match the peak extinction wavelength of the Au nanorod to the peak emission wavelength of 4F9/2→4I15/2 energy transition of Er³+(˜655 nm) nanorods of AR˜2.5 may be used, while in order to match the peak extinction wavelength to the peak emission wavelength of 3H4→3H6 (˜805 nm) nanorods of AR˜4 may be used. Accordingly, in embodiments the AR of the nanomaterials may be configured to ensure that the peak extinction wavelength of the core and the peak emission wavelength of the rare earth shell may be matched to improve efficiency.

FIG. 15B shows the normalized extinction spectra of Au/SiO₂/Yb:Er:Y₂O₃, SiO₂/Yb:Er:Y₂O₃ and Au/SiO₂/Yb:Tm:Y₂O₃ core/shell nanorod solutions along with emission spectrum associated with the Er³⁺4F9/2→4I15/2 and the Tm³⁺ 3H4→3H6 radiative energy transition. The extinction wavelength of the Au/SiO₂/Yb:Er:Y₂O₃ core/shell nanorod solution spectrally matched the peak emission wavelength of the Er3+ 4F9/2→4I15/2 radiative energy transition and the Au/SiO₂/Yb:Tm:Y₂O₃ core/shell nanorod solution spectrally matched the peak emission wavelength of the Tm³⁺ 3H4→3H6 radiative energy transition in order to optimize energy transfer between the plasmonic and fluorescent components of the hybrid core/shell nanorod. The extinction spectrum of the Au/SiO₂/Yb:Er:Y₂O₃ qualitatively resembled the extinction spectrum of Au/SiO₂ core/shell nanorod reference solutions, however, the extinction intensity of the rare earth containing core/shell nanorod colloidal solution were higher in select regions than the extinction of the Au/SiO₂ core/shell nanorod colloids. The increased extinction intensity is attributed to the rare earth shell.

### SUMMARY

An increase in the short circuit current (J_{sc}) and photo conversion efficiency (PCE) of two organic photovoltaic (OPV) polymer systems by incorporating octadecyltrimethoxysilane (OTMS) functionalized gold/silica (Au/SiO₂) and spectrally tailored (Au/SiO₂/Yb:Er:Y₂O₃) core/shell nanomaterials, such as nanorods have the potential to further enhance OPV performance when used as additives in OPV active layers at the Au LSPR and rare earth quantum emitter light core/shell nanospheres and nanorods into their active layers is described. A shell layer, such as SiO₂ or multilayer SiO₂/Yb:Er:Y₂O₃ was added onto the Au core nanospheres and nanorods in order to provide an electrically insulating surface that didn't interfere with carrier generation and transport inside the active layer and/or spectral tunability. Functionalization of the core/shell nanoparticles with the OTMS organic ligand was necessary in order to transfer the core/shell nanoparticles into an OPV polymer-compatible solvent such as dichlorobenzene (DCB). OTMS-functionalized Au/SiO₂ core/shell nanorods and nanospheres were incorporated in the active layers of two OPV polymer systems: a poly(3-hexylthiophene):[6,6]-phenyl-C61-butyric acid methyl ester (P3HT:PCB₆₀M)-based OPV device and a poly[2,6-4,8-di(5-ethylhexylthienyl)benzo[1,2-b;3,4-b]dithiophene-alt-5-dibutyloctyl-3,6-bis(5-bromothiophen-2-yl) pyrrolo[3,4-c]pyrrole-1,4-dione] (PBDTT-DPP:PC₆₀13 M)-based OPV device.

For the P3HT:PC₆₀BM polymer with a band edge ˜700 nm, the incorporation of Au/SiO₂ core/shell nanospheres (˜540 nm peak extinction) in the active layer led to a 2.7% increase in PCE. The addition of the core/shell nanorods with an aspect ratio (AR) ˜2.5 (extinction peak, Δₚₑₐₖ=670 nm) resulted in an 7.1% improvement in photon conversion efficiency (PCE), while for the PBDTT-DPP:PC₆₀BM polymer with a band edge ˜860 nm, the addition of core/shell nanorods of AR˜4 (extinction peak, Δₚₑₐₖ=830 nm) resulted in a 14.4% improvement in PCE. The addition of Au/SiO₂ core/shell nanospheres to the P3HT:PC₆₀BM-polymer resulted in a 1.2% improvement in PCE, while their addition to a PBDTT-DPP:PC₆₀BM polymer resulted in a 9.2% improvement. The PCE and J_{sc} enhancements were consistent with external quantum efficiency (EQE) measurements and the EQE enhancements spectrally matched the extinction spectra of Au/SiO₂ nanospheres and nanorods in both OPV polymer systems. The results support the viability of the approach of increasing OPV solar cell efficiency by incorporating spectrally-tuned nanostructures in OPV active layers in order to absorb the highest possible portion of the solar spectrum.

It has also been determined that by increasing the SiO₂ shell thickness to >20 nm, it is possible to confine electromagnetic near field of the Au nanorod in the SiO₂ shell. Observed EQE enhancements derived from incorporation of Au/SiO₂ core/shell nanoparticles with thick SiO₂ shells (>20 nm) in OPV devices would stem primarily from light scattering off of the nanoparticles as opposed to near field effects. A thin layer of SiO₂ (<5 nm) on the other hand ensures that the nanoparticles remain electrically insulating but that the OPV material at the edge of the nanoparticle experiences the enhanced electromagnetic field due to the nanoparticle LSPR near field. In addition, by pairing Au/SiO₂ core/shell nanorods with different SiO₂ shell thicknesses with quantum emitters (either rare earth ions, quantum dots or laser dye) it is possible to enhance the electromagnetic near field on the spontaneous emission rate of the quantum emitters. Additionally, by controlling the Au nanorod aspect ratio, the spectral match between the plasmonic mode and the fluorescent mode can be controlled.

The concentration of the Au/SiO₂ core/shell nanorods also allows additional tunability. In the case of active layer-incorporated Au/SiO₂ core/shell nanoparticles, addition of small amounts of plasmonic nanorods increased the device PCE, but after a certain critical concentration, the addition of core/shell nanorods degrades device performance, and disrupts OPV polymer morphology.

The relative light absorption or scattering contribution to the overall nanoparticle optical response can be designed by changing the size and geometry of Au nanosphere or nanorod core, since larger nanoparticles generally scatter light more efficiently than smaller particles which tend to absorb the majority of the incident light upon them. OPV devices with plasmonic materials embedded in their active layers make a tradeoff between incorporating small (<30 nm) nanoparticles that preferentially absorb light, but disturb active layer morphology to a lesser degree, and larger (>50 nm) nanoparticles that preferentially scatter light but potentially disturb active layer morphology to a greater degree.

Hybrid core/shell nanorods that include optically active materials also have potential. One possible system is Au/SiO₂/Yb:Er:Y₂O₃ core/shell nanorod optical cavity having single crystal Au nanorods of aspect ratio ˜2.5 (plasmon resonance ˜650 nm) and relatively large size (eg. 20 nm diameter×50 nm length rods). Similarly, another possible system is Au/SiO₂/Yb:Tm:Y₂O₃ core/shell nanorod optical cavity having single crystal Au nanorods of aspect ratio ˜4 (plasmon resonance ˜800 nm) (eg. 10 nm diameter×40 nm length rods), a very thin SiO₂ shell (˜1 nm) and a 10 nm thick Yb:Tm:Y₂O₃ with at least a 1020 cm⁻³ Tm³⁺ ion concentration.

### DOCTRINE OF EQUIVALENTS

As can be inferred from the above discussion, the above-mentioned concepts can be implemented in a variety of arrangements in accordance with embodiments of the invention. Accordingly, although the present invention has been described in certain specific aspects, many additional modifications and variations would be apparent to those skilled in the art. It is therefore to be understood that the present invention may be practiced otherwise than specifically described. Thus, embodiments of the present invention should be considered in all respects as illustrative and not restrictive.

What is claimed is:

1. Resonant light absorption and scattering organic photovoltaic materials comprising:
a multilayer nanostructure having a core formed of a noble metal and having a shell disposed thereon having:
a first shell layer disposed atop the core being formed of a passivating material, and
a second shell layer disposed atop the first shell layer being formed of an optically active material said first shell layer being or optically active character;
wherein the multilayer nanostructure has disposed thereon at least one functional ligand capable of placing the nanostructure into solution with an organic solvent in an active layer of an organic photovoltaic system;
wherein the core of the nanostructure exerts a local surface plasmon resonance near field absorption enhancement over the absorption of light by the organic photovoltaic active layer over the wavelength band of the plasmon resonance of the nanostructure core; and
wherein the optically active material has optical activity at a wavelength band that overlaps with the peak extinction of the local surface plasmon resonance wavelength band of the nanostructure core.

2. The materials of claim 1, wherein the nanostructure is a non-symmetric elongated body, selected from one of a nanosphere, nanostar, nanocube and nanorod.

3. The materials of claim 1, wherein the noble metal is selected from the group consisting of palladium, silver, platinum and gold, wherein the passivation layer is an oxide, and wherein the optically active material is a rare earth material.

4. An organic photovoltaic system comprising:
an active light absorbing layer, said layer being formed of an organic polymer;
a plurality of multilayer nanostructures each having:
a core formed of a noble metal,
a shell disposed thereon formed of a passivating material, and
wherein the multilayer nanostructure has disposed thereon at least one functional ligand capable of placing the nanostructure into solution with the organic polymer in the active layer; and
wherein the core of the nanostructure exerts a local surface plasmon resonance near field absorption enhancement over the absorption of light by the organic photovoltaic active layer over the wavelength band of the plasmon resonance of the nanostructure core.

5. The system of claim 4, wherein the nanostructure is a non-symmetric elongated body, selected from one of a nanosphere, nanostar, nanocube and nanorod.

6. The system of claim 4, wherein the noble metal is selected from the group consisting of palladium, silver, platinum and gold.

7. The system of claim 4, wherein the absorption and scattering of the nanostructure is at least partially controlled by the size and geometry of the noble metal core.

8. The system of claim 4, wherein the shell is a passivation layer that is electrically insulating.

9. The system of claim 4, wherein the passivating material is an oxide.

10. The system of claim 4, wherein the functional ligand is an organosilane.

11. The system of claim 4, wherein the nanostructures are disposed within the active light absorbing layer in a concentration of from 0.4 to 2.0 mg/ml.

12. An organic photovoltaic system comprising:
an active light absorbing layer, said layer being formed of an organic polymer;
a plurality of multilayer nanostructures each having:
a core formed of a noble metal,
a first shell layer disposed atop the core being formed of a passivating material,
a second shell layer disposed atop the first shell layer being formed of an optically active material, and
wherein the multilayer nanostructure has disposed thereon at least one functional ligand capable of placing the nanostructure into solution with the organic polymer in the active layer;
wherein the core of the nanostructure exerts a local surface plasmon resonance near field absorption enhancement over the absorption of light by the organic photovoltaic active layer over the wavelength band of the plasmon resonance of the nanostructure core; and
wherein the optically active material has optical activity at a wavelength band that overlaps with the peak extinction of the local surface plasmon resonance wavelength band of the nanostructure core.

13. The system of claim 12, wherein the nanostructure is a non-symmetric elongated body, selected from one of a nanosphere, nanostar, nanocube and nanorod.

14. The system of claim 12, wherein the noble metal is selected from the group consisting of palladium, silver, platinum and gold.

15. The system of claim 12, wherein the absorption and scattering of the nanostructure is at least partially controlled by the size and geometry of the noble metal core.

16. The system of claim 12, wherein the shell is a passivation layer that is electrically insulating.

17. The system of claim 12, wherein the passivating material is an oxide.

18. The system of claim 12, wherein the functional ligand is an organosilane.

19. The system of claim 12, wherein the optically active layer is formed of Er³⁺:Y₂O₃.

20. The system of claim 12, wherein the nanostructures are disposed within the active light absorbing layer in a concentration of from 0.4 to 2.0 mg/ml.
